(19) United States
(12) Patent Application Publication
(10) Pub. No.: US 2026/0271402 A1
(43) Pub. Date: Sep. 10, 2026

(54) DISPLAY PANEL AND DISPLAY DEVICE

(71) Applicant: BEIJING SHIYAN TECHNOLOGY CO., LTD., Beijing (CN)

(72) Inventors: Lizhen ZHANG, Beijing (CN); Fuqiang LI, Beijing (CN); Jian GAO, Beijing (CN); Xiaolong LI, Beijing (CN); Hongrun WANG, Beijing (CN); Changfeng LI, Beijing (CN); Zhongyuan WU, Beijing (CN); Xue DONG, Beijing (CN)

(73) Assignee: BEIJING SHIYAN TECHNOLOGY CO., LTD., Beijing (CN)

(21) Appl. No.: 18/998,198

(22) PCT Filed: May 16, 2024
(86) PCT No.: PCT/CN2024/093711

§ 371 Date: Jan. 24, 2025

(30) Foreign Application Priority Data
Jun. 20, 2023 (CN) 202310739030.3

(51) Int. Cl. H10D 86/40; G02F 1/1333; G02F 1/1335; G02F 1/1343; G02F 1/1362; G02F 1/1368

(52) U.S. Cl. CPC H10D 86/441; G02F 1/133357; G02F 1/133512; G02F 1/133514; G02F 1/134336; G02F 1/136286; G02F 1/1368; H10D 86/451

(57) ABSTRACT

Disclosed is a display panel. A pixel in an array substrate of the display panel includes a plurality of sub-pixels of different colors, each of the data lines is connected to a column of sub-pixels arranged in a first direction, and each of the gate lines is connected to at least one sub-pixel arranged in the first direction. In addition, a light-emitting region of the sub-pixel is disposed on both sides of the gate line.

### CROSS-REFERENCE TO RELATED APPLICATIONS

The application is a U.S. national phase application based on PCT/CN2024/093711, filed on May 16, 2024, which claims priority to Chinese Patent Application No. 202310739030.3, filed on Jun. 20, 2023, entitled “DISPLAY PANEL AND DISPLAY DEVICE”, both of which are incorporated by reference herein.

### TECHNICAL FIELD

The present disclosure relates to the field of display technologies, and in particular, relates to a display panel and a display device.

### BACKGROUND

Due to the existence of depth information, three-dimension (3D) display technology can achieve many functions that 2D display does not possess, the application of which is more and more widely with the continuous development of display technology.

### SUMMARY

The present disclosure provides a display panel and a display device. The technical solutions are as follows.

In an aspect, a display panel is provided. The display panel includes an array substrate and a color filter substrate that are arranged oppositely, and a liquid crystal layer disposed between the array substrate and the color filter substrate; wherein the array substrate includes:
a first substrate;
a plurality of pixels disposed on the first substrate, wherein each of the pixels includes a plurality of first sub-pixels of a first color, a plurality of second sub-pixels of a second color, and a plurality of third sub-pixels of a third color, wherein a plurality of sub-pixels of each color are arranged in a first direction, and the plurality of first sub-pixels, the plurality of second sub-pixels, and the plurality of third sub-pixels are arranged in a second direction, the second direction and the first direction intersecting;
a plurality of data lines extending in the first direction and arranged in the second direction, wherein each of the data lines is connected to a column of sub-pixels arranged in the first direction; and
a plurality of gate lines extending in a third direction and arranged in the first direction, wherein each of the gate lines is connected to at least one sub-pixel arranged in the first direction, and a light-emitting region of at least a portion of the plurality of sub-pixels included in the pixel is disposed on both sides of the gate line, the third direction and the first direction intersecting; and
the color filter substrate includes a second substrate and a black matrix layer disposed on the second substrate, wherein the black matrix layer includes a plurality of black matrix structures extending in the first direction and arranged in the second direction, wherein each of the black matrix structures covers at least one of the data lines, and the black matrix layer does not overlap with a target line segment of the gate line, the target line segment being a line segment disposed between adjacent sub-pixels in the first direction and not overlapping with the data line.

In some embodiments, the array substrate further includes a pixel electrode layer disposed on the first substrate, the pixel electrode layer including a plurality of pixel electrodes disposed at intervals;

wherein a shape of an orthographic projection of each of the pixel electrodes on the first substrate is in a strip shape, an extension direction of the pixel electrode intersects the first direction, the second direction, and the third direction, and each of the first sub-pixels, the second sub-pixels, and the third sub-pixels includes one of the pixel electrodes.

In some embodiments, wherein the orthographic projection of the pixel electrode on the first substrate partially overlaps with an orthographic projection of at least one of the gate lines on the first substrate.

In some embodiments, in the second direction, a gap is defined between any adjacent sub-pixels of two colors, and at least two of the plurality of data lines are disposed in a same gap, wherein at least one of the data lines disposed in the same gap is connected to one of the adjacent sub-pixels of the two colors, and at least one of the data lines disposed in the same gap is connected to another of the adjacent sub-pixels of the two colors;
each of the gate lines is connected to at least two sub-pixels that are adjacent in the first direction, the third direction and the first direction intersecting; and
each of the black matrix structures covers at least two of the data lines disposed in the same gap.

In some embodiments, two of the plurality of data lines are disposed in the same gap, wherein one of the two data lines is connected to one of the adjacent sub-pixels of the two colors, and another of the two data lines is connected to another of the adjacent sub-pixels of the two colors; or,

three of the plurality of data lines are disposed in the same gap, wherein one of the three data lines is connected to one of the adjacent sub-pixels of the two colors, and another two of the three data lines are connected to another of the adjacent sub-pixels of the two colors; or, two of the data lines disposed in the same gap are connected to one of the adjacent sub-pixels of the two colors, and another of the data lines is connected to another of the adjacent sub-pixels of the two colors.

In some embodiments, the display panel further includes a common electrode layer, wherein the common electrode layer includes a plurality of first electrode portions arranged in the second direction and a plurality of second electrode portions arranged in the second direction, the plurality of first electrode portions and the plurality of second electrode portions being staggered; wherein
an orthographic projection of each of the first electrode portions on the first substrate is within an orthographic projection of the black matrix structure on the first substrate; and
the second electrode portion includes a plurality of common electrode patterns arranged at intervals in the first direction, one end of each of the common electrode patterns being connected to one of two adjacent first electrode portions, and another end of each of the common electrode patterns being connected to another of the two adjacent first electrode portions;
wherein a shape of an orthographic projection of each of the common electrode patterns on the first substrate is in a strip shape, an extension direction of the common electrode pattern is parallel to an extension direction of a pixel electrode included in the sub-pixel, and an orthographic projection of the common electrode pattern on the first substrate at least partially overlaps with an orthographic projection of the pixel electrodes on the first substrate.

In some embodiments, each of the sub-pixels further includes a switching transistor including a source, a drain, and a channel disposed between the source and the drain, wherein the source is connected to the data line, and the drain is connected to a pixel electrode included in the sub-pixel; and
the array substrate includes a gate layer and a transparent electrode layer in contact with the gate layer, wherein the plurality of gate lines are disposed in the gate layer;
wherein the transparent electrode layer includes a plurality of transparent electrode patterns, wherein in a fourth direction, an orthographic projection of each of the transparent electrode patterns on the first substrate covers an orthographic projection of each of the gate lines on the first substrate; a length of the orthographic projection of the transparent electrode pattern on the first substrate in the fourth direction is greater than a length of the orthographic projection of the gate line on the first substrate in the fourth direction; and the length of the orthographic projection of the transparent electrode pattern on the first substrate in the fourth direction is a length of the channel, the fourth direction being perpendicular to the third direction.

In some embodiments, the array substrate includes a buffer layer, an active layer, a gate insulating layer, the gate layer, the transparent electrode layer, an interlayer dielectric layer, a source-drain layer, a first passivation layer, a first planarization layer, the pixel electrode layer, a second passivation layer, a second planarization layer, and the common electrode layer that are stacked sequentially on the first substrate; wherein
the active layer includes a plurality of active patterns, wherein each of the active patterns includes a source region, a drain region, and a channel region;
the interlayer dielectric layer and the gate insulating layer are each provided with a first via, wherein the first via is configured to expose the source region;
the source-drain layer includes the plurality of data lines and a plurality of source-drain patterns, wherein each of the source-drain patterns is connected to one of the data lines, and each of the source-drain patterns and a source region of one of the active patterns are connected through the first via;
the gate insulating layer, the interlayer dielectric layer, the first passivation layer, and the first planarization layer are each provided with a second via, wherein the second via is configured to expose the drain region;
each pixel electrode in the pixel electrode layer has a first portion disposed within the second via and a second portion disposed on a side of the first planarization layer away from the first substrate, wherein the first portion and the drain region of the active pattern are connected through the second via, and a distance between the first portion and the first substrate is less than a distance between the second portion and the first substrate; and
at least a portion of the second planarization layer is disposed on a side of the first portion away from the first substrate, and a surface of the common electrode layer close to the first substrate is a flat surface.

In some embodiments, the array substrate includes a buffer layer, an active layer, a gate insulating layer, the gate layer, the transparent electrode layer, an interlayer dielectric layer, a source-drain layer, a first passivation layer, an electrode transfer layer, a first planarization layer, the pixel electrode layer, a second passivation layer and the common electrode layer that are stacked sequentially on the first substrate; wherein
the active layer includes a plurality of active patterns, wherein each of the active patterns includes a source region, a drain region, and a channel region;
the interlayer dielectric layer and the gate insulating layer are each provided with a first via, wherein the first via is configured to expose the source region;
the source-drain layer includes the plurality of data lines and a plurality of source-drain patterns, wherein each of the source-drain patterns is connected to one of the data lines, and each of the source-drain patterns and a source region of one of the active patterns are connected through the first via;
the gate insulating layer, the interlayer dielectric layer, and the first passivation layer are each provided with a third via, wherein the third via is configured to expose the drain region;
the electrode transfer layer includes a plurality of electrode transfer patterns, wherein each of the electrode transfer patterns and a drain region of one of the active patterns are connected through the third via, and an orthographic projection of the electrode transfer pattern on the first substrate at least partially overlaps with an orthographic projection of the data line on the first substrate;
the first planarization layer is provided with a fourth via, wherein the fourth via is configured to expose the electrode transfer pattern, and an orthographic projection of the fourth via on the first substrate at least partially overlaps with the orthographic projection of the data line on the first substrate; and
each pixel electrode in the pixel electrode layer has a third portion disposed within the fourth via and a fourth portion disposed on a side of the first planarization layer away from the first substrate, wherein the third portion and the electrode transfer pattern are connected through the fourth via, and a distance between the third portion and the first substrate is less than a distance between the fourth portion and the first substrate.

In some embodiments, the first passivation layer includes a first sub-passivation layer and a second sub-passivation layer; and the array substrate further includes a shielding layer disposed between the first sub-passivation layer and the second sub-passivation layer, wherein the shielding layer includes a plurality of shielding patterns, each of the shielding patterns being disposed between the data line and the electrode transfer pattern; and
in the second direction, an orthographic projection of the shielding pattern on the first substrate covers orthographic projections of at least two data lines on the first substrate, and a length of the shielding pattern in the second direction is less than a length of the black matrix structure in the second direction.

In some embodiments, the array substrate further includes a spacer layer disposed between the first sub-passivation layer and the shielding layer;

wherein an orthographic projection of the spacer layer on the first substrate covers the orthographic projection of the shielding pattern on the first substrate.

In some embodiments, the array substrate includes a source-drain layer, a buffer layer, an active layer, a gate insulating layer, the transparent electrode layer, the gate layer, a first passivation layer, a first planarization layer, an electrode transfer layer, a second passivation layer, a second planarization layer, the pixel electrode layer, a third passivation layer, and the common electrode layer that are stacked sequentially on the first substrate; wherein
the source-drain layer includes the plurality of data lines and a plurality of source-drain patterns, wherein each of the source-drain patterns is connected to one of the data lines;
the buffer layer is provided with a fifth via, the fifth via being configured to expose a portion of one of the source-drain patterns;
the active layer includes a plurality of active patterns, wherein each of the active patterns includes a source region, a drain region, and a channel region, the source region and the source-drain pattern being connected through the fifth via;
the first passivation layer and the first planarization layer are each provided with a sixth via, wherein the sixth via is configured to expose the drain region;
the electrode transfer layer includes a plurality of electrode transfer patterns, wherein each of the electrode transfer patterns has a fifth portion disposed within the sixth via and a sixth portion disposed on a side of the first planarization layer away from the first substrate, the fifth portion and the drain region of the active pattern being connected through the sixth via, and a distance between the fifth portion and the first substrate is less than a distance between the sixth portion and the first substrate;
at least a portion of the second planarization layer is within the sixth via, and a surface of the pixel electrode layer close to the first substrate is a flat surface;
the second passivation layer and the second planarization layer are each provided with a seventh via, wherein the seventh via is configured to expose a portion of the sixth portion; and
each pixel electrode in the pixel electrode layer and one sixth portion are connected through the seventh via.

In some embodiments, the array substrate includes a source-drain layer, a buffer layer, an active layer, a gate insulating layer, the transparent electrode layer, the gate layer, a first passivation layer, an electrode transfer layer, a first planarization layer, the pixel electrode layer, a second passivation layer, and the common electrode layer that are stacked sequentially on the first substrate;
the source-drain layer includes the plurality of data lines and a plurality of source-drain patterns, wherein each of the source-drain patterns is connected to one of the data lines;
the buffer layer is provided with a fifth via, wherein the fifth via is configured to expose a portion of the source-drain pattern;
the active layer includes a plurality of active patterns, wherein each of the active patterns includes a source region, a drain region, and a channel region, the source region and the source-drain pattern being connected through the fifth via;
the first passivation layer is provided with an eighth via, wherein the eighth via is configured to expose the drain region;
the electrode transfer layer includes a plurality of electrode transfer patterns, wherein each of the electrode transfer patterns and the drain region are connected through the eighth via;
the first planarization layer is provided with a ninth via, wherein the ninth via is configured to expose a portion of the electrode transfer pattern; and
the pixel electrode has a seventh portion disposed within the ninth via and an eighth portion disposed on a side of the first planarization layer away from the first substrate, wherein the seventh portion and the electrode transfer pattern are connected through the ninth via, and a distance between the seventh portion and the first substrate is less than a distance between the eighth portion and the first substrate;
wherein the black matrix structure covers the ninth via.

In some embodiments, the pixel electrode has a first pixel portion, a second pixel portion and a third pixel portion, wherein an orthographic projection of the first pixel portion on the first substrate is within an orthographic projection of a first target black matrix structure on the first substrate, an orthographic projection of the second pixel portion on the first substrate is located between the orthographic projection of the first target black matrix structure on the first substrate and an orthographic projection of a second target black matrix structure on the first substrate, an orthographic projection of the third pixel portion on the first substrate is within the orthographic projection of the second target black matrix structure on the first substrate, the first target black matrix structure and the second target black matrix structure being two black matrix structures that are adjacent in the second direction; and

a length of the first pixel portion in the second direction and a length of the third pixel portion in the second direction are both greater than or equal to 1 μm.

In some embodiments, the display panel further includes a lens layer disposed on a side of the color filter substrate away from the array substrate, wherein the lens layer includes a plurality of lens structures, a surface of each of the lens structures away from the array substrate being a curved surface;

wherein a shape of an orthographic projection of the lens structure on the array substrate is in a strip shape, and an extension direction of the lens structure intersects the first direction, the second direction and the third direction.

In some embodiments, the extension direction of the lens structure intersects an extension direction of the pixel electrode included in the sub-pixel.

In some embodiments, in a first condition, the first direction is a pixel column direction of the display panel, the second direction is a pixel row direction of the display panel, and a first conditional angle between the extension direction of the pixel electrode and the second direction is satisfied:

$$tan α 1 = \frac{d - b}{a - c} ;$$

an angle between the extension direction of the lens structure and the second direction is satisfied:

$$tan β = \frac{d}{a - c} ;$$

wherein the a is a length of the sub-pixel in the second direction, the b is a length of the sub-pixel in the first direction, the c is a length of the black matrix structure in the second direction, and the d is a length of the lens structure disposed between the two adjacent black matrix structures portions of the lens structure in the first direction; and
the first condition is that a length in the first direction of a portion of the lens structure disposed in an opening region equal to a maximum distance between two ends of the sub-pixel in the first direction.

In some embodiments, in a second condition, the third direction is parallel to the second direction, and a second conditional angle between the extension direction of the pixel electrode and the second direction is satisfied:

$$tan α2 = \frac{e}{a - c} ;$$

wherein the e is a distance between two adjacent gate lines in the first direction; and
an angle between the extension direction of the pixel electrode and the second direction is a common multiple of the first conditional angle and the second conditional angle; and
the second condition is that a length of a portion of the pixel electrode disposed between adjacent black matrix structures in the first direction is equal to a distance of adjacent gate lines in the first direction.

In some embodiments, in a third condition, the third direction and the second direction intersect, and a third conditional angle between the third direction and the second direction is satisfied:

$$tan γ1 = \frac{e - ( a - c ) tan α 1}{a - c} ;$$

wherein e is a distance between two adjacent gate lines in the first direction; and
the third condition is that a sum of a length in the first direction of a portion of the pixel electrode disposed between adjacent black matrix structures and a length in the first direction of a portion of the gate line disposed between adjacent black matrix structures is equal to a distance of adjacent gate lines in the first direction.

In some embodiments, in a fourth condition, the third direction and the second direction intersect, and a fourth conditional angle between the third direction and the second direction is satisfied:

$$tan γ2 = \frac{2 e - ( a - c ) tan α 1}{a - c} ;$$

wherein e is a distance between two adjacent gate lines in the first direction;
the fourth condition is that a sum of a length in the first direction of a portion of the pixel electrode disposed between adjacent black matrix structures and a length in the first direction of a portion of the gate line disposed between adjacent black matrix structures is equal to a distance between the first target gate line and a second target gate line in the first direction, and a third target gate line is also provided between the first target gate line and the second target gate line, an orthographic projection of the pixel electrode on the first substrate partially overlapping with an orthographic projection of the third target gate line on the first substrate.

In some embodiments, extension directions of the plurality of lens structures in the display panel are parallel, and extension directions of the plurality of pixel electrodes included in the pixel electrode layer in the display panel are parallel.

In another aspect, a display device is provided. The display device includes a power supply assembly and the display panel as described in the above aspect;

wherein the power supply assembly is configured for supplying power to the display panel.

### BRIEF DESCRIPTION OF DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a schematic structural diagram of a display panel according to some embodiments of the present disclosure;

FIG. 2 is a partial schematic diagram of an array substrate and a color filter substrate according to some embodiments of the present disclosure;

FIG. 3 is a schematic diagram of an opening region according to some embodiments of the present disclosure;

FIG. 4 is a schematic diagram of an angle of a pixel electrode according to some embodiments of the present disclosure;

FIG. 5 is a partial schematic diagram of another array substrate and color filter substrate according to some embodiments of the present disclosure;

FIG. 6 is a partial schematic diagram of yet another array substrate and color filter substrate according to some embodiments of the present disclosure;

FIG. 7 is a partial schematic diagram of a common electrode layer according to some embodiments of the present disclosure;

FIG. 8 is a partial cross-sectional view of an array substrate according to some embodiments of the present disclosure;

FIG. 9 is a partial cross-sectional view of another array substrate according to some embodiments of the present disclosure;

FIG. 10 is a partial cross-sectional view of yet another array substrate according to some embodiments of the present disclosure;

FIG. 11 is a partial cross-sectional view of still another array substrate according to some embodiments of the present disclosure;

FIG. 12 is a partial cross-sectional view of still another array substrate according to some embodiments of the present disclosure;

FIG. 13 is a partial cross-sectional view of still another array substrate according to some embodiments of the present disclosure;

FIG. 14 is a partial schematic diagram of a source-drain layer according to some embodiments of the present disclosure;

FIG. 15 is a partial schematic diagram of a buffer layer according to some embodiments of the present disclosure;

FIG. 16 is a partially superimposed schematic diagram of a source-drain layer and a buffer layer according to some embodiments of the present disclosure;

FIG. 17 is a partial schematic diagram of an active layer according to some embodiments of the present disclosure;

FIG. 18 is a partially superimposed schematic diagram of a source-drain layer, a buffer layer, and an active layer according to some embodiments of the present disclosure;

FIG. 19 is a partial schematic diagram of a transparent electrode layer according to some embodiments of the present disclosure;

FIG. 20 is a partially superimposed schematic diagram of a source-drain layer, a buffer layer, an active layer, and a transparent electrode layer according to some embodiments of the present disclosure;

FIG. 21 is a partial schematic diagram of a gate layer according to some embodiments of the present disclosure;

FIG. 22 is a partially superimposed schematic diagram of a source-drain layer, a buffer layer, an active layer, a transparent electrode layer, and a gate layer according to some embodiments of the present disclosure;

FIG. 23 is a partial schematic diagram of a first passivation layer and a first planarization layer according to some embodiments of the present disclosure;

FIG. 24 is a partially superimposed schematic diagram of a source-drain layer, a buffer layer, an active layer, a transparent electrode layer, a gate layer, a first passivation layer, and a first planarization layer according to some embodiments of the present disclosure;

FIG. 25 is a partial schematic diagram of an electrode transfer layer according to some embodiments of the present disclosure;

FIG. 26 is a partially superimposed schematic diagram of a source-drain layer, a buffer layer, an active layer, a transparent electrode layer, a gate layer, a first passivation layer, a first planarization layer, and an electrode transfer layer according to some embodiments of the present disclosure;

FIG. 27 is a partial schematic diagram of a second planarization layer according to some embodiments of the present disclosure;

FIG. 28 is a partially superimposed schematic diagram of a source-drain layer, a buffer layer, an active layer, a transparent electrode layer, a gate layer, a first passivation layer, a first planarization layer, an electrode transfer layer, and a second planarization layer according to some embodiments of the present disclosure;

FIG. 29 is a partial schematic diagram of a second passivation layer according to some embodiments of the present disclosure;

FIG. 30 is a partially superimposed schematic diagram of a source-drain layer, a buffer layer, an active layer, a transparent electrode layer, a gate layer, a first passivation layer, a first planarization layer, an electrode transfer layer, a second planarization layer, and a second passivation layer according to some embodiments of the present disclosure;

FIG. 31 is a partial schematic diagram of a pixel electrode layer according to some embodiments of the present disclosure;

FIG. 32 is a partially superimposed schematic diagram of a source-drain layer, a buffer layer, an active layer, a transparent electrode layer, a gate layer, a first passivation layer, a first planarization layer, an electrode transfer layer, a second planarization layer, a second passivation layer, and a pixel electrode layer according to some embodiments of the present disclosure;

FIG. 33 is a partial schematic diagram of a common electrode layer according to some embodiments of the present disclosure;

FIG. 34 is a partially superimposed schematic diagram of a source-drain layer, a buffer layer, an active layer, a transparent electrode layer, a gate layer, a first passivation layer, a first planarization layer, an electrode transfer layer, a second planarization layer, a second passivation layer, a pixel electrode layer, and a common electrode layer according to some embodiments of the present disclosure;

FIG. 35 is a partial schematic diagram of a black matrix layer according to some embodiments of the present disclosure;

FIG. 36 is a partially superimposed schematic diagram of a source-drain layer, a buffer layer, an active layer, a transparent electrode layer, a gate layer, a first passivation layer, a first planarization layer, an electrode transfer layer, a second planarization layer, a second passivation layer, a pixel electrode layer, a common electrode layer, and a black matrix layer according to some embodiments of the present disclosure;

FIG. 37 is a partial schematic diagram of a source-drain layer according to some embodiments of the present disclosure;

FIG. 38 is a partial schematic diagram of a buffer layer according to some embodiments of the present disclosure;

FIG. 39 is a partially superimposed schematic diagram of a source-drain layer and a buffer layer according to some embodiments of the present disclosure;

FIG. 40 is a partial schematic diagram of an active layer according to some embodiments of the present disclosure;

FIG. 41 is a partially superimposed schematic diagram of a source-drain layer, a buffer layer, and an active layer according to some embodiments of the present disclosure;

FIG. 42 is a partial schematic diagram of a transparent electrode layer according to some embodiments of the present disclosure;

FIG. 43 is a partially superimposed schematic diagram of a source-drain layer, a buffer layer, an active layer, and a transparent electrode layer according to some embodiments of the present disclosure;

FIG. 44 is a partial schematic diagram of a gate layer according to some embodiments of the present disclosure;

FIG. 45 is a partially superimposed schematic diagram of a source-drain layer, a buffer layer, an active layer, a transparent electrode layer, and a gate layer according to some embodiments of the present disclosure;

FIG. 46 is a partial schematic diagram of a first passivation layer according to some embodiments of the present disclosure;

FIG. 47 is a partially superimposed schematic diagram of a source-drain layer, a buffer layer, an active layer, a transparent electrode layer, a gate layer, and a first passivation layer according to some embodiments of the present disclosure;

FIG. 48 is a partial schematic diagram of an electrode transfer layer according to some embodiments of the present disclosure;

FIG. 49 is a partially superimposed schematic diagram of a source-drain layer, a buffer layer, an active layer, a transparent electrode layer, a gate layer, a first passivation layer, and an electrode transfer layer according to some embodiments of the present disclosure;

FIG. 50 is a partial schematic diagram of a first planarization layer according to some embodiments of the present disclosure;

FIG. 51 is a partially superimposed schematic diagram of a source-drain layer, a buffer layer, an active layer, a transparent electrode layer, a gate layer, a first passivation layer, an electrode transfer layer, and a first planarization layer according to some embodiments of the present disclosure;

FIG. 52 is a partial schematic diagram of a pixel electrode layer according to some embodiments of the present disclosure;

FIG. 53 is a partially superimposed schematic diagram of a source-drain layer, a buffer layer, an active layer, a transparent electrode layer, a gate layer, a first passivation layer, an electrode transfer layer, a first planarization layer, and a pixel electrode layer according to some embodiments of the present disclosure;

FIG. 54 is a partial schematic diagram of a common electrode layer according to some embodiments of the present disclosure;

FIG. 55 is a partially superimposed schematic diagram of a source-drain layer, a buffer layer, an active layer, a transparent electrode layer, a gate layer, a first passivation layer, an electrode transfer layer, a first planarization layer, a pixel electrode layer, a second passivation layer, and a common electrode layer according to some embodiments of the present disclosure;

FIG. 56 is a partial schematic diagram of a black matrix layer according to some embodiments of the present disclosure;

FIG. 57 is a partially superimposed schematic diagram of a source-drain layer, a buffer layer, an active layer, a transparent electrode layer, a gate layer, a first passivation layer, an electrode transfer layer, a first planarization layer, a pixel electrode layer, a second passivation layer, a common electrode layer, and a black matrix layer according to some embodiments of the present disclosure;

FIG. 58 is a brightness curve at different gray levels according to some embodiments of the present disclosure;

FIG. 59 is a brightness curve of positions of adjacent pixel electrodes at different grayscales according to some embodiments of the present disclosure;

FIG. 60 is a partial schematic diagram of a display panel according to some embodiments of the present disclosure;

FIG. 61 is a brightness curve of a sub-pixel according to some embodiments of the present disclosure;

FIG. 62 is a schematic diagram of a moiré pattern according to some embodiments of the present disclosure;

FIG. 63 is a partial schematic diagram of an extension direction of a lens structure being parallel to an extension direction of a pixel electrode according to some embodiments of the present disclosure;

FIG. 64 is a partial schematic diagram of an extension direction of a lens structure intersecting an extension direction of a pixel electrode according to some embodiments of the present disclosure;

FIG. 65 is a partial schematic diagram of a pixel electrode, a common electrode pattern, and a black matrix structure according to some embodiments of the present disclosure;

FIG. 66 is a partial schematic diagram of a pixel electrode, a gate line, and a black matrix structure according to some embodiments of the present disclosure;

FIG. 67 is a partial schematic diagram of another pixel electrode, a gate line, and a black matrix structure according to some embodiments of the present disclosure;

FIG. 68 is a partial schematic diagram of yet another pixel electrode, a gate line, and a black matrix structure according to some embodiments of the present disclosure; and

FIG. 69 is a schematic structural diagram of a display device according to some embodiments of the present disclosure.

### DETAILED DESCRIPTION

To make the objective, technical solutions, and advantages of the present disclosure clearer, embodiments of the present disclosure will be further described in detail with reference to the accompanying drawings.

In the related art, a display panel includes a plurality of data lines extending in a first direction and arranged in a second direction, a plurality of gate lines extending in the second direction and arranged in the first direction, and a plurality of sub-pixels arranged in an array. Each of the data lines is connected to a column of sub-pixels to provide a data signal for the column of sub-pixels, and each of the gate lines is connected to a row of sub-pixels to provide a gate signal for the row of sub-pixels. The sub-pixels included in the display panel can realize light emission under the joint control of the data lines and the gate lines. And, the display panel further includes a black matrix layer. The black matrix layer includes a plurality of first black matrix structures extending in a first direction and arranged in a second direction, and a plurality of second black matrix structures extending in a second direction and arranged in a first direction. Each of the first black matrix structures covers one data line, and each of the second black matrix structures covers one gate line.

However, the above solution makes it difficult to realize a continuous display of the display panel in the first direction or the second direction, and the display effect is poor.

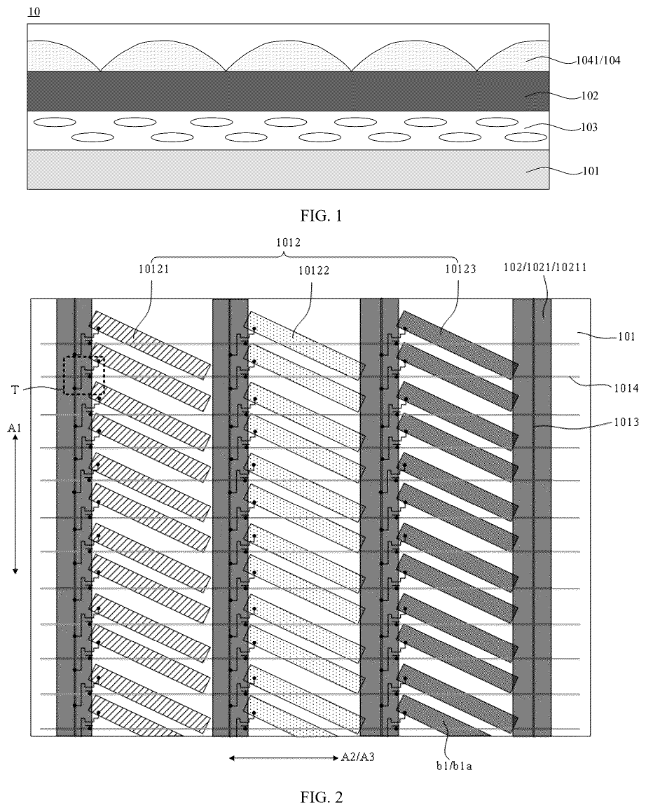

FIG. 1 is a schematic structural diagram of a display panel according to some embodiments of the present disclosure. As can be seen with reference to FIG. 1, the display panel 10 includes an array substrate 101 and a color filter substrate 102 that are arranged oppositely, and a liquid crystal layer 103 disposed between the array substrate 101 and the color filter substrate 102.

FIG. 2 is a partial schematic diagram of an array substrate and a color filter substrate according to some embodiments of the present disclosure. As can be seen with reference to FIG. 2, the array substrate 101 includes a first substrate 1011, a plurality of pixels 1012, a plurality of data (source) lines 1013, and a plurality of gate (gate) lines 1014.

Referring to FIG. 2, the plurality of pixels 1012 are disposed on the first substrate 1011, each of the pixels 1012 includes a plurality of first sub-pixels 10121 of a first color, a plurality of second sub-pixels 10122 of a second color, and a plurality of third sub-pixels 10123 of a third color. The plurality of sub-pixels of each color are arranged in a row in the first direction (A1). One pixel 1012 is shown in FIG. 2 includes twelve first sub-pixels 10121, twelve second sub-pixels 10122, and twelve third sub-pixels 10123.

In some embodiments, the first color, the second color, and the third color are different from each other. Exemplarily, the first color is red (R), the second color is green (G), and the third color is blue (B). That is, the first sub-pixel 10121 is a red sub-pixel, the second sub-pixel 10122 is a green sub-pixel, and the third sub-pixel 10123 is a blue sub-pixel.

In addition, the plurality of first sub-pixels 10121, the plurality of second sub-pixels 10122, and the plurality of third sub-pixels 10123 are arranged in the second direction A2. In some embodiments, the second direction A2 and the first direction A1 intersect. For example, the first direction A1 is a pixel column direction of the display panel 10, and the second direction A2 is a pixel row direction of the display panel 10.

Referring to FIG. 2, the plurality of data lines 1013 extend in the first direction A1 and are arranged in the second direction A2. Each of the data lines 1013 is connected to a column of sub-pixels arranged in the first direction A1 for providing a data signal to the column of sub-pixels.

Referring to FIG. 2, the display panel 10 includes a plurality of gate lines 1014 extending in a third direction A3 and arranged in the first direction A1 (the third direction A3 and the second direction A2 are parallel in FIG. 2). Each of the gate lines 1014 is connected to at least one sub-pixel arranged in the first direction A1, and the light-emitting region of at least a portion of the plurality of sub-pixels included in the pixel is disposed on both sides of the gate lines 1014. The third direction A3 and the first direction A1 intersect.

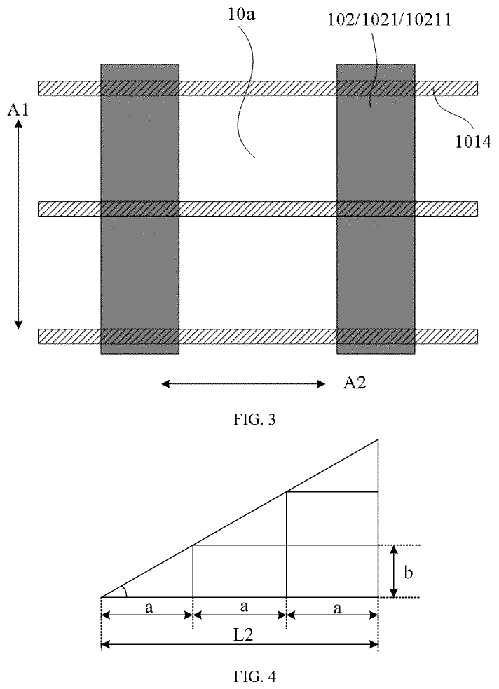

Referring to FIG. 3, the display panel 10 includes a plurality of opening regions 10a (two opening regions 10a are shown in FIG. 3). Each of the opening regions 10a is a region surrounded by two black matrix structures 10211 arranged and adjacent in the second direction A2 and two gate lines 1014 arranged and adjacent in the first direction A1. By providing the light-emitting region of the sub-pixel disposed on both sides of the gate line 1014, the light-emitting region of the sub-pixel may span the gate line 1014 and be located in the two opening regions 10a arranged in the first direction A1, so as to occupy at least two of the opening regions 10a arranged in the first direction A1. For each sub-pixel, the light-emitting region of the sub-pixel occupies two opening regions 10a, which facilitates realizing a continuous display of the two opening regions 10a.

Referring to FIG. 2, the color filter substrate 102 includes a second substrate (not shown in FIG. 2) and a black matrix (BM) layer 1021 disposed on the second substrate. The black matrix layer 1021 includes a plurality of black matrix structures 10211 extending in the first direction A1 and arranged in the second direction A2. Each of the black matrix structures 10211 covers at least one data line 1013.

In addition, an orthographic projection of the black matrix layer 1021 on the first substrate 1011 does not overlap with an orthographic projection of a target line segment of the gate line 1014 on the first substrate 1011. The target line segment is a line segment disposed between adjacent sub-pixels in the first direction A1 and not overlapping with the data line 1013. That is, the black matrix layer 1021 does not include a black matrix structure for covering the gate lines 1014.

In the embodiments of the present disclosure, as the gate lines 1014 are not covered by the black matrix structures 10211, the light-emitting regions of the plurality of sub-pixels arranged in the first direction A1 included in the display panel 10 have a better continuity, which in turn enables the display panel 10 to realize a continuous display in the first direction A1, and the display effect of the display panel 10 is better.

In summary, the embodiments of the present disclosure provide a display panel. The pixel in an array substrate of the display panel includes a plurality of sub-pixels of different colors, each of the data lines is connected to a column of sub-pixels arranged in a first direction, and each of the gate lines is connected to at least one sub-pixel arranged in the first direction. In addition, the light-emitting region of the sub-pixel is disposed on both sides of the gate line, i.e., span two opening regions disposed on both sides of the gate line, which facilitates realizing the continuous display of two opening regions arranged in the first direction. Moreover, as the black matrix structure does not cover the target line segment of the gate line, the influence of the black matrix structure on the continuous display in the first direction can be avoided, and the continuous display of the display panel in the first direction is ensured, and the display effect of the display panel is better.

Referring to FIG. 2, it can also be seen that the array substrate 101 further includes a pixel electrode layer b1 disposed on the first substrate 1011. The pixel electrode layer b1 includes a plurality of pixel electrodes b1a disposed at intervals. An orthographic projection of the pixel electrodes b1a on the first substrate 1011 is in a strip shape. The extension direction of the pixel electrode b1a intersects the first direction A1, the second direction A2, and the third direction A3. That is, the pixel electrode b1a is inclined with respect to the data line 1013 and the gate line 1014. In some embodiments, the distance between adjacent pixel electrodes b1a may range from 5 micrometers (μm) to 10 μm.

Each of the first sub-pixels 10121, the second sub-pixels 10122, and the third sub-pixels 10123 includes one pixel electrode b1a. The one pixel electrode b1a is configured to form a light-emitting region of one sub-pixel.

In the embodiments of the present disclosure, the light-emitting region of the sub-pixel being disposed on both sides of the gate line 1014 can be realized by inclining the pixel electrode b1a of the sub-pixel. That is, the pixel electrode b1a of the sub-pixel can occupy at least two opening regions 10a arranged in the first direction A1. Moreover, the pixel electrodes b1a are inclined to avoid the generation of rainbow patterns in the display panel 10.

As the pixel electrodes b1a are inclined, in combination with FIGS. 2 and 3, an orthographic projection of the pixel electrode b1a on the first substrate 1011 partially overlaps with an orthographic projection of the at least one gate line 1014 on the first substrate 1011. That is, one end of the pixel electrode b1a is disposed in an opening region 10a on the first side of the gate line 1014, and the other end is disposed in an opening region 10a on the second side of the gate line 1014, and the pixel electrode b1a can across the gate line 1014 and be arranged in two opening regions 10a on both sides of the gate line 1014.

In the embodiments of the present disclosure, the extension directions of the plurality of pixel electrodes b1a in the display panel 10 are parallel (the extension direction of the pixel electrode b1a is a fixed direction, and an inclination angle of the pixel electrode b1a with respect to the second direction A2 is a fixed angle), so as to ensure display homogeneity in different regions of the display panel 10. In addition, for any pixel electrode b1a, the extension direction of the pixel electrode b1a is collinear to the extension direction of the pixel electrode b1a in different rows in the first direction A1. That is, the extension of the pixel electrode b1a along the inclination angle is capable of completely overlapping with the pixel electrode b1a in different rows.

Referring to FIG. 4, an angle between the extension direction of the pixel electrode b1a and the second direction A2 is satisfied:

$$tan α = \frac{n \times b}{a} = \frac{i}{j} \qquad For mula ( 1 )$$

In the above formula (1), a is the length of the sub-pixel in the second direction A2, b is the length of the sub-pixel in the first direction A1, and n, i, and j are positive integers. The length a of the sub-pixel in the second direction A2 is equal to the sum of the length of the black matrix structure 10211 in the second direction A2 and the distance between black matrix structure 10211 and the adjacent black matrix structure 10211 in the second direction A2.

In addition, the length a of the sub-pixel in the second direction A2 is equal to the length L2 of the pixel 1012 in the second direction A2 divided by the number of sub-pixels in the second direction A2 included in the pixel 1012. For example, in the case that the number of sub-pixels in the second direction A2 included in the pixel 1012 is 3, the length a of the sub-pixel in the second direction A2 is equal to L2/3. The length b of the sub-pixel in the first direction A1 is equal to the length L1 of the pixel 1012 in the first direction A1 divided by the number of sub-pixels in the first direction A1 included in the pixel 1012 (L1 is not labeled in FIG. 4). For example, in the case that the number of sub-pixels in the second direction A2 included in the pixel 1012 is 12, the length b of the sub-pixel in the second direction A2 is equal to L1/12.

In the embodiments of the present disclosure, the optimal value of the angle α is related to the type of the actual product. For example, in the case that the display panel is applied in a mobile terminal (smartphone) or a tablet computer, as the user may use the mobile terminal and the tablet computer with a landscape display or a portrait display, the product optimal value of the angle α may be 45° (degrees) when the 3D display effect needs to be realized in both the landscape and portrait directions. Alternatively, in the case that the display panel is applied in a laptop, a desktop, or a television, as the user usually uses the laptop, the desktop, or the television with a landscape display, the product optimal value of the angle may be 90° when the 3D display is required only in the landscape direction.

For a display panel with a certain number of views (the number of views can represent the number of sub-pixels of any color included in each pixel), different angles α are calculated by selecting different n through the above formula (1). Based on the type of the product, the angle α that is closest to the product optimal value is selected from the calculated angles α as the optimal angle α for the number of views. That is, the angle α needs to satisfy the above formula (1) and is closest to the product optimal value. In this case, the n corresponding to the optimal angle α calculated by the above formula (1) can be the most reasonable n.

In some embodiments, in the case that the pixel 1012 includes twelve first sub-pixels 10121, twelve second sub-pixels 10122, and twelve third sub-pixels 10123 (this scheme may be referred to as a 12 view), the angle between the extension direction of the pixel electrode b1a and the second direction A2 preferably may be arctan (1/2), arctan (3/4), and 45°. In the case that the pixel 1012 includes thirteen first sub-pixels 10121, thirteen second sub-pixels 10122, and thirteen third sub-pixels 10123 (this scheme may be referred to as 13 view), the angle between the extension direction of the pixel electrode b1a and the second direction A2 may preferably be arctan (3/13), arctan (6/13), arctan (9/13), arctan (12/13), and arctan (15/13). In the case that the pixel 1012 includes eleven first sub-pixels 10121, eleven second sub-pixels 10122, and eleven third sub-pixels 10123 (this scheme may be referred to as 11 view), the angle between the extension direction of the pixel electrode b1a and the second direction A2 may preferably be arctan (12/11), arctan (9/11), arctan (6/11), and arctan (15/11).

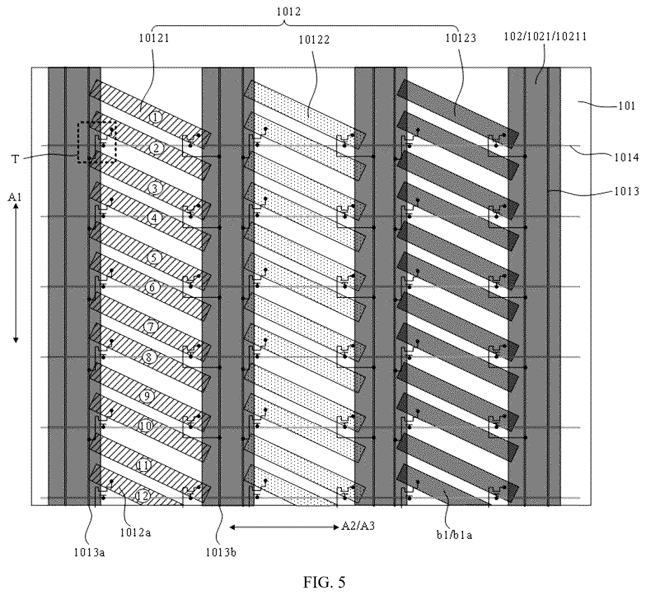

In the embodiments of the present disclosure, in the second direction A2, a gap is defined between any adjacent sub-pixels of two colors. For example, in FIG. 5, a plurality of first sub-pixels 10121 of a first color and a plurality of second sub-pixels 10122 of a second color are adjacent in the second direction A2, and a gap is defined between the plurality of first sub-pixels 10121 and the plurality of second sub-pixels 10122. Alternatively, the plurality of second sub-pixels 10122 of the second color and a plurality of third sub-pixels 10123 of a third color are adjacent in the second direction A2, and a gap is defined between the plurality of second sub-pixels 10122 and the plurality of third sub-pixels 10123.

With continued reference to FIG. 5, at least two data lines 1013 are disposed in a gap between any adjacent sub-pixels of two colors. At least one data line 1013 disposed in the same gap is connected to one of the adjacent sub-pixels of the two colors, and the at least one data line 1013 disposed in the same gap is connected to another of the adjacent sub-pixels of the two colors. For example, two data lines 1013 are disposed in the gap in FIG. 5, one of which is connected to a sub-pixel of a first color, and the other data line 1013 is connected to a sub-pixel of a second color.

In the embodiments of the present disclosure, for a plurality of target sub-pixels (taking 1012a in the figure as an example) included in the pixel 1012 that are of the same color and arranged in the first direction A1, the plurality of target sub-pixels have at least two corresponding target data lines (taking 1013a and 1013b in the figure as an example). At least one of the at least two target data lines is disposed on a first side of the plurality of sub-pixels in the second direction A2, and at least one of the at least one target data line 1013 is disposed on a second side of the plurality of sub-pixels in the second direction A2.

In the at least two corresponding target data lines, at least one target data line is used to connect with a portion of the plurality of target sub-pixels, and at least one target data line is used to connect with another portion of the plurality of target sub-pixels. That is, the plurality of sub-pixels arranged in the first direction A1 may be connected to the at least two data lines 1013, which are used to provide data signals for the plurality of sub-pixels.

Referring to FIG. 5, target sub-pixels connected to two target data lines providing data signals for the plurality of target sub-pixels are staggered. For example, in the case that the pixel 1012 in FIG. 5 includes twelve first sub-pixels 10121 as twelve target sub-pixels, a target data line 1013a disposed on a first side (as shown on the left side) of the twelve first sub-pixels 10121 is connected to the first sub-pixels 10121 with the serial numbers 2, 4, 6, 8, 10, and 12 of the twelve first sub-pixels 10121, and a target data line 1013b on a second side (as shown on the right side) of the twelve first sub-pixels 10121 is connected to the first sub-pixels 10121 with the serial numbers 1, 3, 5, 7, 9, and 11.

By this design, a column of sub-pixels can be connected to at least two data lines 1013, which in turn can provide data signals for the same column of sub-pixels through the at least two data lines 1013. By this design, the number of gate lines 1014 required for each pixel 1012 can be reduced, which in turn can reduce the number of gate lines 1014 included in the entire display panel 10, and can provide gate signals to the pixels 1012 included in the display panel 10 through a smaller number of gate lines 1014.

Exemplarily, the number of gate lines 1014 of the display panel 10 providing gate signals to each pixel 1012 may be equal to the number of sub-pixels of any one color included in the pixel 1012 divided by the number of data lines 1013 with the gap design. Assuming that the pixel 1012 includes twelve first sub-pixels 10121, twelve second sub-pixels 10122, and twelve third sub-pixels 10123, and that the gap is designed with two data lines 1013, the number of gate lines 1014 connected to the sub-pixels included in the pixel 1012 is 12+2=6.

And as the display panel 10 includes fewer gate lines 1014 than the number of sub-pixels arranged in the first direction A1 (i.e., the number of rows of sub-pixels), each gate line 1014 may be connected to at least two sub-pixels arranged in the first direction A1.

In some embodiments, referring to FIG. 5, in the case that the pixel 1012 includes twelve first sub-pixels 10121, twelve second sub-pixels 10122, and twelve third sub-pixels 10123, and two data lines 1013 are provided for each gap, the display panel 10 includes six gate lines 1014 connected to the sub-pixels in the pixel 1012. Moreover, the six gate lines 1014 are arranged in the first direction A1, and each gate line 1014 is connected to two adjacent sub-pixels of the twelve sub-pixels included in the pixel 1012 arranged in the first direction A1.

For each pixel 1012, each gate line 1014 may be connected to two first sub-pixels 10121, two second sub-pixels 10122, and two third sub-pixels 10123 in one pixel 1012. In addition, in the two first sub-pixels 10121 connected by each gate line 1014, one of the first sub-pixels 10121 is connected to one data line 1013 disposed in a gap on a first side of the two first sub-pixels 10121, and the other first sub-pixel 10121 is connected to one data line 1013 disposed in a gap on a second side of the two first sub-pixels 10121. In the two second sub-pixels 10122 connected by each gate line 1014, one of the second sub-pixels 10122 is connected to one data line 1013 disposed in a gap on a first side of the two second sub-pixels 10122, and the other second sub-pixel 10122 is connected to one data line 1013 disposed in a gap on a second side of the two second sub-pixels 10122. In the two third sub-pixels 10123 connected by each gate line 1014, one of the third sub-pixels 10123 is connected to one data line 1013 disposed in a gap on a first side of the two third sub-pixels 10123, and the other third sub-pixel 10123 is connected to one data line 1013 disposed in a gap on a second side of the two third sub-pixels 10123.

In the embodiments of the present disclosure, each black matrix structure 10211 covers at least two data lines 1013 disposed in the same gap. i.e., an orthographic projection of each black matrix structure 10211 on the first substrate 1011 covers orthographic projections of all data lines 1013 in the same gap on the first substrate 1011. For example, assuming that each gap is designed with two data lines 1013, the orthographic projection of each black matrix structure 10211 on the first substrate 1011 covers orthographic projections of the two data lines 1013 disposed in the same gap on the first substrate 1011. Alternatively, assuming that each gap is designed with three data lines 1013, the orthographic projection of each black matrix structure 10211 on the first substrate 1011 covers orthographic projections of the three data lines 1013 disposed in the same gap on the first substrate 1011.

In the embodiments of the present disclosure, each column of sub-pixels is connected to at least two data lines 1013 (which may be referred to as the Mutil Source scheme), the number of data lines 1013 corresponding to the pixels 1012 can increase, which in turn reduces the number of gate lines 1014 required for the pixels 1012. Moreover, the charging time H for each line of pixels can be satisfied:

$$H = \frac{1}{f \times ( m + r ) \times k} \qquad Formula ( 2 )$$

In the above formula (2), f is the refresh frequency, m is the gate line resolution, r is the number of dummy gate lines, and k is the number of gate lines 1014 within each pixel 1012. In the case that the number k of gate lines 1014 required for the pixel 1012 decreases, the charging time H increases, which in turn ensures that each sub-pixel is more adequately charged. The gate line resolution may refer to the number of rows of pixels 1012, or may refer to the number of pixels 1012 included in each column of pixels 1012.

As an optional implementation, referring to FIG. 5, two data lines 1013 are arranged in a gap between adjacent sub-pixels of the first target color and sub-pixels of the second target color. One of the data lines 1013 disposed in the same gap is connected to the sub-pixels of the first target color, and the other data line 1013 is connected to the sub-pixels of the second target color. In the scheme shown in FIG. 5, the number of gated lines 1014 included in the display panel 10 is half of the number of sub-pixels included in the display panel 10 that are arranged in the first direction A1.

As another optional implementation, referring to FIG. 6, three data lines 1013 are arranged in a gap between adjacent sub-pixels of the first target color and sub-pixels of the second target color. Two of the data lines (1013a and 1013c) disposed in the same gap are connected to the sub-pixels of the first target color, and another data line (1013b) is connected to the sub-pixels of the second target color. Alternatively, two of the data lines disposed in the same gap are connected to the sub-pixels of the first target color, and another data line is connected to the sub-pixels of the second target color. In the scheme shown in FIG. 6, the number of gate lines 1014 included in the display panel 10 is ⅓ of the number of sub-pixels included in the display panel 10 that are arranged in the first direction A1.

Alternatively, a greater number of data lines 1013 may be arranged in a gap between adjacent sub-pixels of the first target color and sub-pixels of the second target color. A portion of the data lines 1013 disposed in the same gap is connected to the sub-pixels of the first target color, and another portion of the data lines 1013 is connected to the sub-pixels of the second target color. The embodiments of the present disclosure do not limit the number of data lines 1013 disposed in the gap.

It should be noted that the more the number of data lines 1013 disposed in the gap is, the more complicated the layout design of the display panel 10 will be, such that the number of data lines disposed in the gap cannot be too many. Normally, two data lines 1013 or three data lines 1013 disposed in the gap are sufficient.

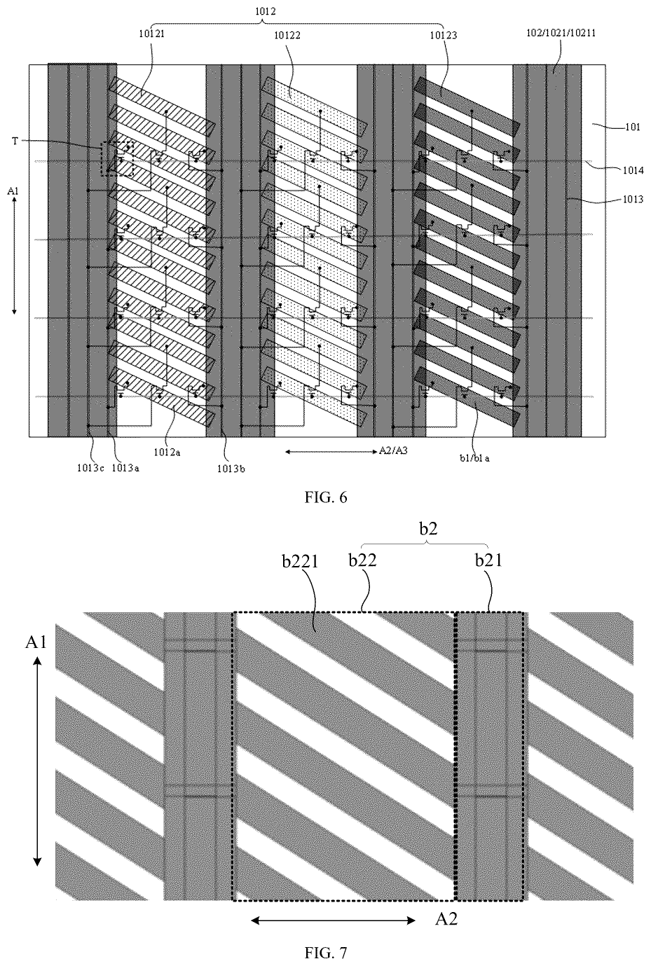

Referring to FIG. 7, the array substrate 101 further includes a common (com) electrode layer b2. Liquid crystal molecules in the liquid crystal layer 103 included in the display panel 10 can be deflected under the combined drive of the pixel electrode layer b1 and the common electrode layer b2, thereby causing the display panel 10 to emit light. Referring to FIG. 7, the common electrode layer b2 includes a plurality of first electrode portions b21 arranged in the second direction A2 and a plurality of second electrode portions b22 arranged in the second direction A2. The plurality of first electrode portions b21 and the plurality of second electrode portions b22 are staggered.

An orthographic projection of the first electrode portion b21 on the first substrate 1011 is within an orthographic projection of the black matrix structure 10211 on the first substrate 1011. The second electrode portion b22 includes a plurality of common electrode patterns b221 arranged at intervals in the first direction A1. One end of each common electrode pattern b221 is connected to one of the two adjacent first electrode portions b21, and another end is connected to the other first electrode portion b21 of the two adjacent first electrode portions b21.

The shape of an orthographic projection of each common electrode pattern b221 on the first substrate 1011 is in a strip shape, an extension direction of the common electrode pattern b221 is parallel to the extension direction of the pixel electrode b1a. The orthographic projection of the common electrode pattern b221 on the first substrate 1011 at least partially overlaps with the orthographic projection of the pixel electrode b1a on the first substrate 1011. In some embodiments, a distance between adjacent common electrode patterns b221 ranges from 3 μm to 10 μm.

Referring to FIG. 7, the first electrode portion b21 is an integral structure, and the plurality of common electrode patterns b221 of the second electrode portion b22 are connected through the first electrode portion b21. In this way, the common electrode layer b2 transmits common electrode signals.

It should be noted that the second electrode portion b22 of the common electrode layer b2 may also be an integral structure, i.e., the common electrode layer b2 may be an entire electrode layer covering the display region of the display panel 10. The embodiments of the present disclosure do not limit the specific design of the common electrode layer b2.

Referring to FIG. 2, FIG. 5, and FIG. 6, each sub-pixel further includes a switching transistor T. The switching transistor T includes a source, a drain, and a channel disposed between the source and the drain. The source is connected to the data line 1013, and the drain is connected to the pixel electrode b1a.

In the embodiment of the present disclosure, as the gate line 1014 is not covered by the black matrix structure 10211, the width of the gate line 1014 may be appropriately reduced (i.e., the length of an orthographic projection of the gate line 1014 on the first substrate 1011 in a fourth direction A4 may be reduced) in order to minimize the influence of the gate line 1014 on the display effect. The reduction of the width of the gate line 1014 results in a smaller length of the channel of the switching transistor T. However, the length of the channel affects the electrical characteristics and operating performance of the switching transistor T. Therefore, the length of the channel cannot be designed to be smaller. The fourth direction A4 is perpendicular to the third direction A3. In FIG. 2, FIG. 5, and FIG. 6, the fourth direction A4 is a pixel column direction.

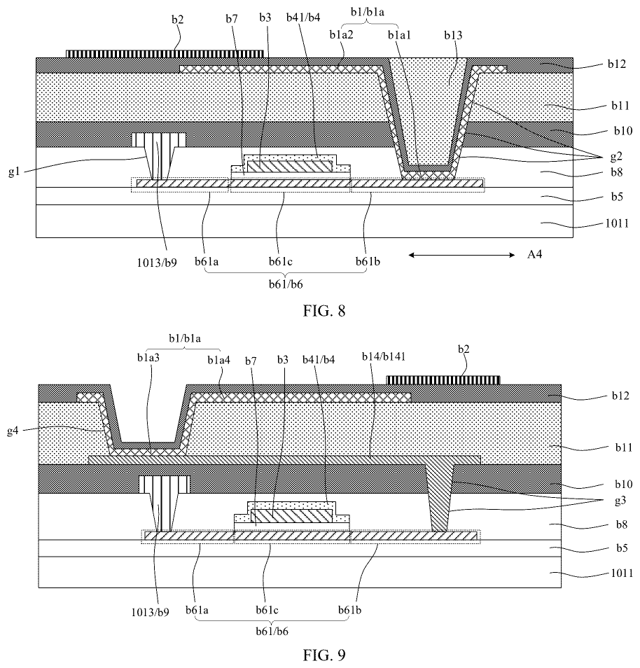

FIG. 8 is a partial cross-sectional view of an array substrate according to some embodiments of the present disclosure. Referring to FIG. 8, the array substrate 101 includes a gate layer b3 and a transparent electrode layer b4 in contact with the gate layer b3. The gate line 1014 is disposed in the gate layer b3. The transparent electrode layer b4 includes a plurality of transparent electrode patterns b41. In the fourth direction A4, an orthographic projection of the transparent electrode pattern b41 on the first substrate 1011 covers an orthographic projection of the gate line 1014 on the first substrate 1011. In addition, the length of the orthographic projection of the transparent electrode patterns b41 on the first substrate 1011 in the fourth direction A4 is greater than the length of the orthographic projection of the gate line 1014 on the first substrate 1011 in the fourth direction A4.

As the transparent electrode pattern b41 is in direct contact with the gate line 1014, the length of the orthographic projection of the transparent electrode pattern b41 on the first substrate 1011 in the fourth direction A4 is the length of the channel. As a result, in the case that the width of the gate line 1014 is small, the length of the channel can be increased by the transparent electrode pattern b41, and the electrical characteristics and operating performance of the switching transistor can be ensured. Moreover, as the transparent electrode pattern b41 is made of a transparent material, the size of the opening region 10a of the display panel 10 will not be affected despite the wider width of the transparent electrode pattern b41, and the display effect of the display panel 10 can be ensured.

Referring to FIG. 8, the array substrate 101 includes a buffer layer b5, an active layer (poly) b6, a gate insulating layer (gate insulator, GI) b7, a gate layer b3, a transparent electrode layer b4, and an interlayer dielectric layer (inter level dielectric, ILD) b8, a source-drain layer b9, a first passivation layer (PVX) b10, a first planarization layer (PLN) b11, a pixel electrode layer b1, a second passivation layer b12, a second planarization layer b13, and a common electrode layer b2 that are stacked sequentially on the first substrate 1011.

The active layer b6 includes a plurality of active patterns b61, and each active pattern b61 includes a source region b61a, a drain region b61b, and a channel region b61c. Each active pattern b61 is used to form part of the switching transistor T.

The interlayer dielectric layer b8 and the gate insulating layer b7 are each provided with a first via g1. The first via g1 is configured to expose the source region b61a of the active pattern b61. In FIG. 8, the first via g1 is disposed in the interlayer dielectric layer b8 only because the gate insulating layer b is disposed only in the channel region b61c and does not cover the source region b61a.

The source-drain layer b9 includes a plurality of data lines 1013 and a plurality of source-drain patterns. Each source-drain pattern is connected to one data line 1013, and each source-drain pattern and a source region b61a of one active pattern b61 are connected through the first via g1. The source-drain pattern and the data line 1013 in FIG. 8 are represented using the same pattern.

The gate insulating layer b7, the interlayer dielectric layer b8, the first passivation layer b10, and the first planarization layer b11 are each provided with a second via g2. The second via g2 is configured to expose the drain region b61b.

Each pixel electrode b1a in the pixel electrode layer b1 has a first portion b1a1 disposed within the second via g2 and a second portion bla2 disposed on a side of the first planarization layer b11 away from the first substrate 1011. The first portion b1a1 and the drain region b61b of the active pattern b61 are connected through the second via g2, and a distance between the first portion b1a1 and the first substrate 1011 is less than a distance between the second portion bla2 and the first substrate 1011. That is, a surface of the pixel electrode b1a away from the first substrate 1011 is a non-flat surface.

At least a portion of the second planarization layer b13 is disposed on a side of the first portion b1a1 away from the first substrate 1011, i.e., the second planarization layer b13 may be filled within the second via g2, such that a surface of the common electrode layer b2 close to the first substrate 1011 is a flat surface.

Typically, in the case that the surface of the common electrode layer b2 close to the first substrate 1011 is not flat, a surface of the array substrate 101 close to the color filter substrate 102 is caused to not flat, which in turn will result in the liquid crystal layer 103 being filled unevenly, affecting the display effect of the display panel 10. Thus, in order to avoid affecting the display effect due to the surface being not flat, the orthographic projection of the black matrix structure 10211 on the first substrate 1011 can cover the orthographic projection of the second via g2 on the first substrate 1011, such that the region where the second via g2 is located is a non-opening region. However, such a design will result in a wider width of the black matrix structure 10211 in the second direction A2, affecting the opening ratio of the display panel 10.

In the embodiments of the present disclosure, the flatness of the surface of the common electrode layer b2 close to the first substrate 1011 is improved by filling the second planarization layer b13 to the second via g2. In this way, the filling uniformity of the liquid crystal layer 103 can be improved, and the controllability of the liquid crystal molecules in the liquid crystal layer 103 can be ensured, such that the second via g2 can be covered without using the black matrix structure 10211. Further, the width of the black matrix structure 10211 in the second direction A2 can be smaller to improve the opening ratio of the display panel 10. The second planarization layer b13 in FIG. 8 is disposed only in the second via g2, and the second planarization layer b13 may also be disposed on a side of the second passivation layer b12 away from the first substrate 1011.

FIG. 9 is a partial cross-sectional view of another array substrate according to some embodiments of the present disclosure. Referring to FIG. 9, the array substrate 101 includes a buffer layer b5, an active layer b6, a gate insulating layer b7, a gate layer b3, a transparent electrode layer b4, an interlayer dielectric layer b8, a source-drain layer b9, a first passivation layer b10, an electrode transfer layer b14, a first planarization layer b11, a pixel electrode layer b1, a second passivation layer b12, and a common electrode layer b2 that are stacked sequentially on the first substrate 1011.

The active layer b6 includes a plurality of active patterns b61, and each active pattern b61 includes a source region b61a, a drain region b61b, and a channel region b61c. Each active pattern b61 is used to form part of the switching transistor T.

The interlayer dielectric layer b8 and the gate insulating layer b7 have a first via g1, the first via g1 being for exposing a source region b61a of the active pattern b61.

The source-drain layer b9 includes a plurality of data lines 1013 and a plurality of source-drain patterns. Each source-drain pattern is connected to one data line 1013, and each source-drain pattern and a source region b61a of one active pattern b61 are connected through the first via g1.

The gate insulating layer b7, the interlayer dielectric layer b8, and the first passivation layer b10 are each provided with a third via g3. The third via g3 is configured to expose the drain region b61b. In FIG. 9, as the gate insulating layer b is only in the channel region b61c and does not cover the drain region b61b, the third via g3 is only in the interlayer dielectric layer b8 and the first passivation layer b10.

The electrode transfer layer b14 includes a plurality of electrode transfer patterns b141. Each electrode transfer pattern b141 and a drain region b61b of one active pattern b61 are connected through the third via g3. Moreover, an orthographic projection of the electrode transfer pattern b141 on the first substrate 1011 at least partially overlaps with an orthographic projection of the data line 1013 on the first substrate 1011.

The first planarization layer b11 is provided with a fourth via g4. The fourth via g4 is configured to expose the electrode transfer pattern b141, and an orthographic projection of the fourth via g4 on the first substrate 1011 at least partially overlaps with the orthographic projection of the data line 1013 on the first substrate 1011.

Each pixel electrode b1a in the pixel electrode layer b1 has a third portion b1a3 disposed within the fourth via g4 and a fourth portion b1a4 disposed on a side of the first planarization layer b11 away from the first substrate 1011. The third portion b1a3 and the drain region b61b of the active pattern b61 are connected through the fourth via g4, and a distance between the third portion b1a3 and the first substrate 1011 is less than a distance between the fourth portion b1a4 and the first substrate 1011. That is, the surface of the pixel electrode b1a away from the first substrate 1011 is a non-flat surface.

In the array substrate 101 shown in FIG. 9, the active pattern b61 and the pixel electrode b1a are connected by the electrode transfer pattern b141. Moreover, an orthographic projection of the connection position (the fourth via g4) of the electrode transfer pattern b141 and the pixel electrode b1a on the first substrate 1011 partially overlaps with the orthographic projection of the data line 1013 on the first substrate 1011.

Typically, the orthographic projection of the black matrix structure 10211 on the first substrate 1011 covers the orthographic projection of the data line 1013 on the first substrate 1011. Thus the orthographic projection of the fourth via g4 on the first substrate 1011 partially overlaps with the orthographic projection of the data line 1013 on the first substrate 1011, which can cause the orthographic projection of the black matrix structure 10211 on the first substrate 1011 to also cover the orthographic projection of the fourth via g4 on the first substrate 1011. As a result, even though the liquid crystal layer 103 at the fourth via g4 is unevenly filled, the display effect of the display panel 10 is not affected based on the black matrix structure 10211 covering the fourth via g4.

In the array substrate 101 described in FIG. 9, due to an additional electrode transfer layer b14 being provided, the electrode transfer layer b14 is connected to the pixel electrodes b1a (the electrode transfer layer b14 and the pixel electrodes b1a transmit the same signal), the distance between the electrode transfer layer b14 and the source-drain layer b9 is closer in the direction of the thickness of the film layer. Further, the electrode transfer layer b14 and the source-drain layer b9 can cause the data signal transmitted by the data line 1013 of the source-drain layer b9 to interfere with the pixel 1012 due to the closer distance.

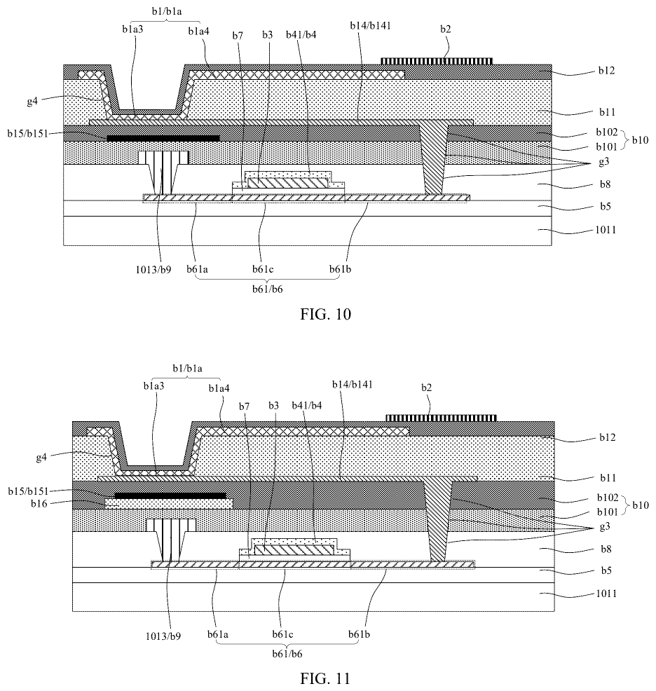

For the above reasons, referring to FIG. 10, the first passivation layer b10 includes a first sub-passivation layer b101 and a second sub-passivation layer b102. The array substrate 101 further includes a shielding layer b15 disposed between the first sub-passivation layer b101 and the second sub-passivation layer b102. The shielding layer b15 includes a plurality of shielding patterns b151. The shielding pattern b151 is disposed between the data line 1013 and the electrode transfer pattern b141.

In the second direction A2, an orthographic projection of the shielding pattern b151 on the first substrate 1011 covers orthographic projections of the at least two data lines 1013 on the first substrate 1011, and a length of the shielding pattern b151 in the second direction A2 is less than a length of the black matrix structure 10211 in the second direction A2.

As the shielding pattern b151 covers at least two data lines 1013 in the second direction A2, the data lines 1013 disposed in the source-drain layer b9 can be prevented from interfering with the electrode transfer pattern b141 disposed in the electrode transfer layer b14, thereby ensuring the display effect of the display panel 10. Moreover, the length of the shielding pattern b151 in the second direction A2 is smaller than the length of the black matrix structure 10211 in the second direction A2, thus the design of the shielding pattern b151 will not affect the size of the opening region 10a of the display panel 10. However, the distance between the shielding pattern b151 and the data lines 1013 in the source-drain layer b9 in the thickness direction is relatively close, which will generate a certain capacitive loading on the data lines 1013.

Further, referring to FIG. 11, the array substrate 101 further includes a spacer layer b16 disposed between the first sub-passivation layer b101 and the shielding layer b15. An orthographic projection of the spacer layer b16 on the first substrate 1011 covers at least an orthographic projection of the shielding pattern b151 on the first substrate 1011. The distance between the shielding layer b15 and the source-drain layer b9 in the thickness direction can thus be increased to reduce the capacitance loading generated by the shielding layer b15 on the data lines 1013.

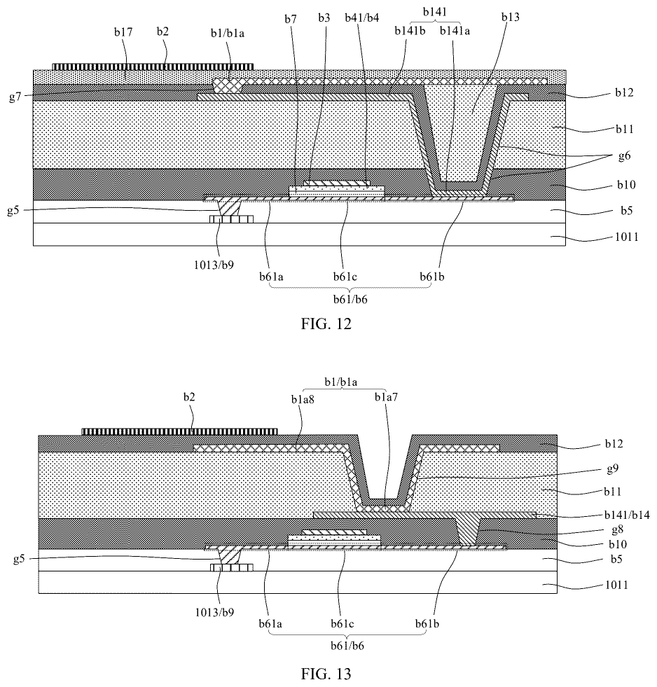

FIG. 12 is a partial cross-sectional view of yet another array substrate according to some embodiments of the present disclosure. Referring to FIG. 12, the array substrate 101 includes a source-drain layer b9, a buffer layer b5, an active layer b6, a gate insulating layer b7, a transparent electrode layer b4, a gate layer b3, a first passivation layer b10, a first planarization layer b11, an electrode transfer layer b14, a second passivation layer b12, a second planarization layer b13, a pixel electrode layer b1, a third passivation layer b17, and a common electrode layer b2 that are stacked sequentially on the first substrate 1011. The connection of the array substrate 101 shown in FIG. 12 may be a top gate bottom connection (TGBC).

The source-drain layer b9 includes a plurality of data lines 1013, and a plurality of source-drain patterns. Each source-drain pattern is connected to one data line 1013.

The buffer layer b5 is provided with a fifth via g5. The fifth via g5 is configured to expose a portion of the source-drain pattern, and the fifth via g5 is used for a subsequent active pattern b61 to be connected to the source-drain pattern.

The active layer b6 includes a plurality of active patterns b61. Each active pattern b61 includes a source region b61a, a drain region b61b, and a channel region b61c, the source region b61a and the source-drain pattern being connected through a fifth via g5.

The first passivation layer b10 and the first planarization layer b11 are each provided with a sixth via g6. The sixth via g6 is configured to expose the drain region b61b, and the sixth via g6 is used for a subsequent electrode transfer pattern b141 to be connected to the drain region b61b.

The electrode transfer layer b14 includes a plurality of electrode transfer patterns b141. Each electrode transfer pattern b141 has a fifth portion b141a disposed within a sixth via g6, and a sixth portion b141b disposed on a side of the first planarization layer b11 away from the first substrate 1011. The fifth portion b141a and the drain region b61b of the active pattern b61 are connected through the sixth via g6. A distance between the fifth portion b141a and the first substrate 1011 is less than a distance between the sixth portion b141b and the first substrate 1011. That is, the surface of the electrode transfer layer b14 away from the first substrate 1011 is a non-flat surface.

At least a portion of the second planarization layer b13 is disposed within the sixth via g6, and a surface of the pixel electrode layer b1 close to the first substrate 1011 is a flat surface.

The second passivation layer b12 and the second planarization layer b13 are each provided with a seventh via g7. The seventh via g7 is configured to expose a portion of the sixth portion b141b, and the seventh via g7 is used for a subsequent pixel electrode b1a to be connected to the electrode transfer pattern b141.

Each pixel electrode b1a in the pixel electrode layer b1 and one sixth portion b141b are connected through a seventh via g7.

Typically, in the case that the surface of the pixel electrode layer b1 close to the first substrate 1011 is not flat, it will result in the surface of the array substrate 101 close to the color filter substrate 102 not being flat, which in turn will result in the liquid crystal layer 103 being filled unevenly, affecting the display effect of the display panel 10. Thus, in order to avoid affecting the display effect due to the uneven surface, the orthographic projection of the black matrix structure 10211 on the first substrate 1011 can cover the orthographic projection of the sixth via g6 on the first substrate 1011, such that the region where the sixth via g6 is located is a non-opening region. However, such a design will result in a wider width of the black matrix structure 10211 in the second direction A2, affecting the opening ratio of the display panel 10.

In the embodiments of the present disclosure, the flatness of the surface of the pixel electrode layer b1 close to the first substrate 1011 is improved by filling the second planarization layer b13 into the sixth via g6. In this way, the filling uniformity of the liquid crystal layer 103 can be improved to ensure the controllability of the liquid crystal molecules in the liquid crystal layer 103, and thus the sixth via g6 can be covered without using the black matrix structure 10211. Further, the width of the black matrix structure 10211 in the second direction A2 can be smaller to improve the opening ratio of the display panel 10.

In the embodiments of the present disclosure, FIG. 13 is a partial cross-sectional view of yet another array substrate according to some embodiments of the present disclosure. Referring to FIG. 13, the array substrate 101 includes a source-drain layer b9, a buffer layer b5, an active layer b6, a gate insulating layer b7, a transparent electrode layer b4, a gate layer b3, a first passivation layer b10, an electrode transfer layer b14, a first planarization layer b11, a pixel electrode layer b1, a second passivation layer b12, and a common electrode layer b2 that are stacked sequentially on the first substrate 1011. The array substrate 101 of FIG. 13 shows that the connection of the array substrate 101 may be a TGBC.

The source-drain layer b9 includes a plurality of data lines 1013 and a plurality of source-drain patterns. Each source-drain pattern is connected to one data line 1013.

The buffer layer b5 is provided with a fifth via g5. The fifth via g5 is configured to expose a portion of the source-drain pattern, and the fifth via g5 is used for a subsequent active pattern b61 to be connected to the source-drain pattern.

The active layer b6 includes a plurality of active patterns b61. Each active pattern b61 includes a source region b61a, a drain region b61b, and a channel region b61c, the source region b61a and the source-drain pattern being connected through the fifth via g5.

The first passivation layer b10 is provided with an eighth via g8. The eighth via g8 is configured to expose the drain region b61b, and the eighth via g8 is used for a subsequent electrode transfer pattern b141 to be connected to the drain region b61b.

The electrode transfer layer b14 includes a plurality of electrode transfer patterns b141. Each electrode transfer pattern b141 and the drain region b61b are connected through the eighth via g8.

The first planarization layer b11 is provided with a ninth via g9. The ninth via g9 is configured to expose a portion of the electrode transfer pattern b141.

The pixel electrode b1a has a seventh portion b1a7 disposed within the ninth via g9 and an eighth portion b1a8 disposed on a side of the first planarization layer b11 away from the first substrate 1011. The seventh portion b1a7 and the electrode transfer pattern b141 are connected through the ninth via g9, and a distance between the seventh portion b1a7 and the first substrate 1011 is less than a distance between the eighth portion b1a8 and the first substrate 1011. That is, the surface of the pixel electrode b1a away from the first substrate 1011 is a non-flat surface.

In this scheme, the two data lines 1013 are provided in each gap, and an orthographic projection of the ninth via g9 on the first substrate 1011 can be located between the two data lines 1013. As the black matrix structure 10211 itself covers the two data lines 1013, the black matrix structure 10211 can also cover the ninth via g9 between the two data lines 1013. Thus, although the liquid crystal layer 103 at the ninth via g9 is unevenly filled, as the black matrix structure 10211 will cover the ninth via g9, the unevenness of the position of the ninth via g9 does not affect the display effect of the display panel 10.

In the embodiments of the present disclosure, the layer stacking relationship of the transparent electrode layer b4 and the gate layer b3 may be exchanged, for example, in FIGS. 8 to 11, the transparent electrode layer b4 is disposed on a side of the gate layer b3 away from the first substrate 1011, and in FIGS. 12 and 13, the gate layer b3 is disposed on a side of the transparent electrode layer b4 away from the first substrate 1011. The embodiments of the present disclosure do not limit the layer stacking relationship between the transparent electrode layer b4 and the gate layer b3.

In the embodiments of the present disclosure, in order to facilitate a clear representation of the individual film layers, taking the array substrate 101 shown in FIG. 12 as an example, each film layer of the array substrate 101 is briefly described below in terms of individual single layers as well as step-by-step stacking manner.

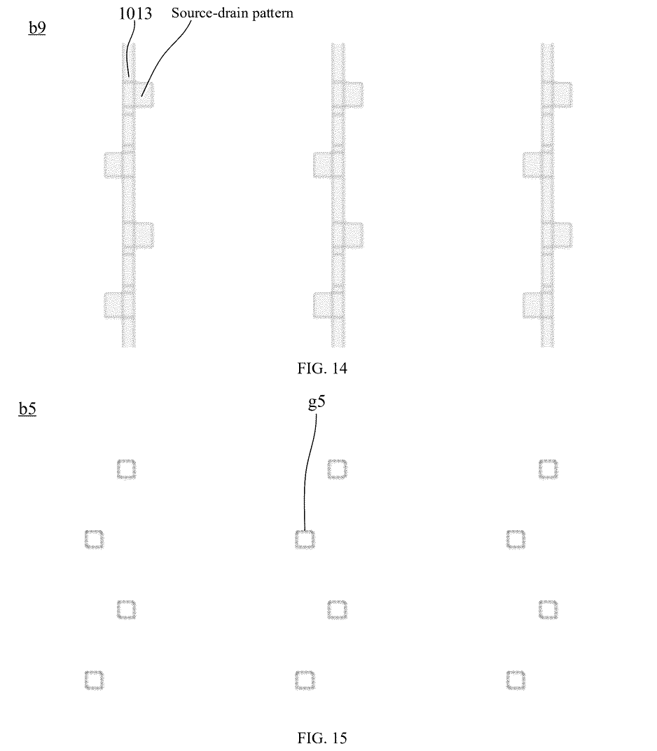

FIG. 14 is a partial schematic diagram of a source-drain layer according to some embodiments of the present disclosure. As can be seen with reference to FIG. 14, the source-drain layer b9 includes a plurality of data lines 1013 and a source-drain pattern. The source-drain pattern is a pattern protruding from a side of the data line 1013 and is of an integral structure with the data line 1013.

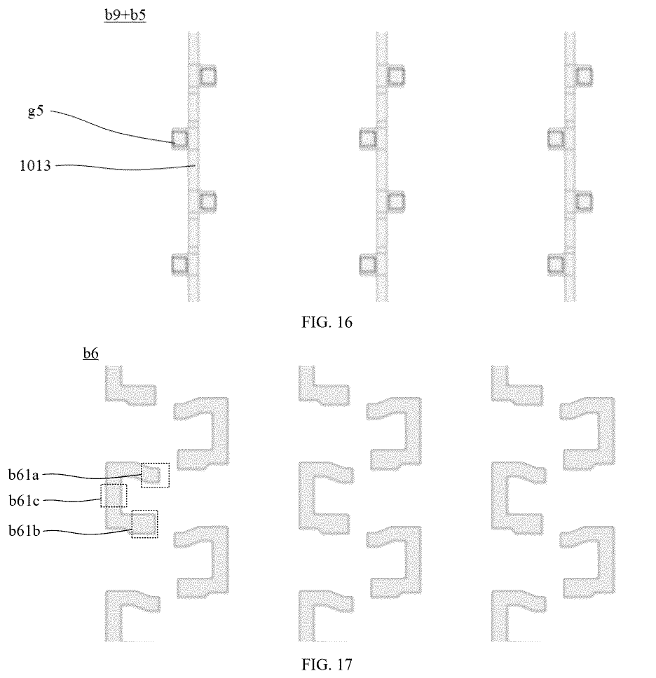

FIG. 15 is a partial schematic diagram of a buffer layer according to some embodiments of the present disclosure. FIG. 16 is a partially superimposed schematic diagram of a source-drain layer and a buffer layer according to some embodiments of the present disclosure. Combined with FIG. 15 and FIG. 16, the buffer layer b5 may be provided with a fifth via g5 for exposing at least a portion of the source-drain pattern, and the fifth via g5 for a subsequent active pattern b61 to be connected to the source-drain pattern. In order to facilitate the illustration of individual fifth vias g5 in the buffer layer b5, a fill pattern is used in FIG. 13 and FIG. 14 to represent the fifth vias g5. Other regions not drawn with a fill pattern are used to represent regions where the buffer layer b5 is made of a solid material.

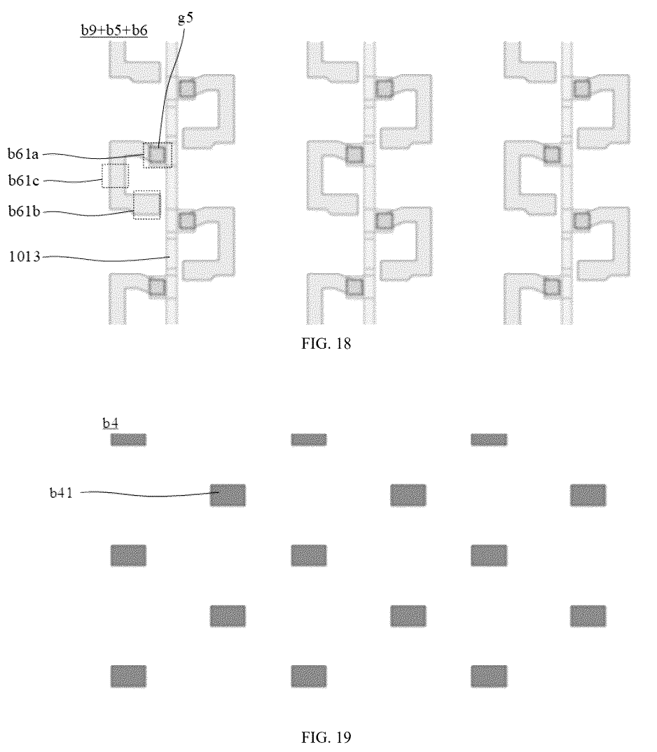

FIG. 17 is a partial schematic diagram of an active layer according to some embodiments of the present disclosure. FIG. 18 is a partially superimposed schematic diagram of a source-drain layer, a buffer layer, and an active layer according to some embodiments of the present disclosure. Combined with FIG. 17 and FIG. 18, the active layer b6 includes a plurality of active patterns b61. With respect to the plurality of active patterns b61 corresponding to one data line 1013, a portion of the active patterns b61 is disposed on a first side of the one data line 1013, and another portion of the active patterns b61 is disposed on a second side of the one data line 1013.

Each active pattern b61 and the corresponding data line 1013 are connected through the fifth via g5 in the buffer layer b5.

In the embodiments of the present disclosure, the display panel 10 includes a gate insulating layer b7 disposed on a side of the active layer b6 away from the first substrate 1011 for insulating the the active layer b6 from the subsequently formed gate layer b3. This gate insulating layer b7 may be a whole covered film layer and is no longer schematized using the accompanying drawings.

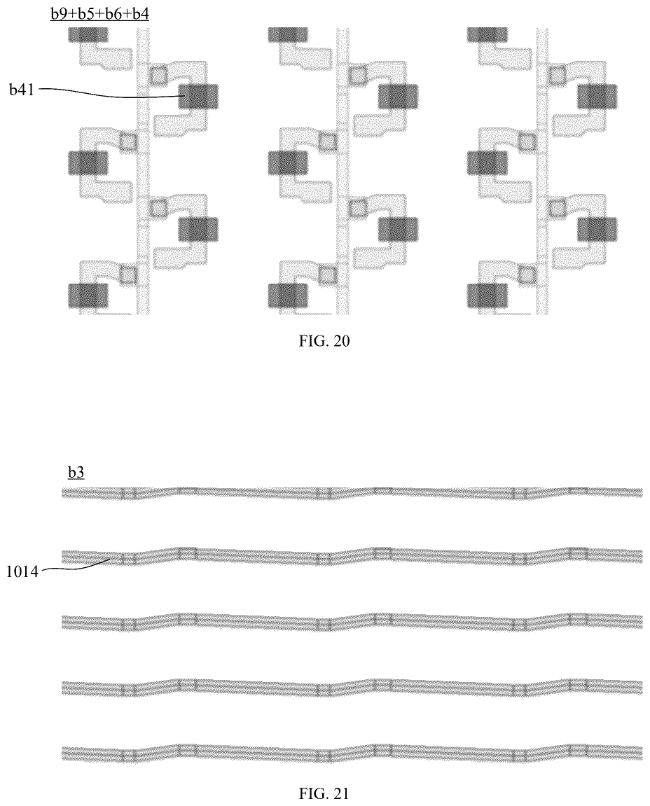

FIG. 19 is a partial schematic diagram of a transparent electrode layer according to some embodiments of the present disclosure. FIG. 20 is a partially superimposed schematic diagram of a source-drain layer, a buffer layer, an active layer, and a transparent electrode layer according to some embodiments of the present disclosure. Combined with FIG. 19 and FIG. 20, the transparent electrode layer b4 includes a plurality of transparent electrode patterns b41. An orthographic projection of each transparent electrode pattern b41 on the first substrate 1011 partially overlaps with an orthographic projection of the active pattern b61 on the first substrate 1011.

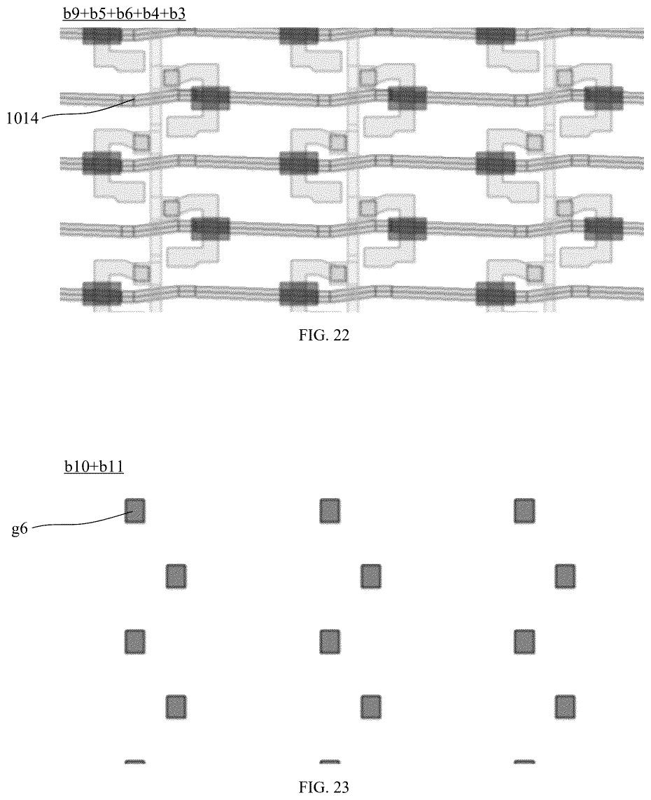

FIG. 21 is a partial schematic diagram of a gate layer according to some embodiments of the present disclosure. FIG. 22 is a partially superimposed schematic diagram of a source-drain layer, a buffer layer, an active layer, a transparent electrode layer, and a gate layer according to some embodiments of the present disclosure. Combined with FIG. 21 and FIG. 22, the gate layer b3 includes a plurality of gate lines 1014. An orthographic projection of each gate line 1014 on the first substrate 1011 partially overlaps with an orthographic projection of the transparent electrode pattern b41 on the first substrate 1011. The gate line 1014 and the transparent electrode pattern b41 are in direct contact for forming the channel region b61c of the switching transistor.

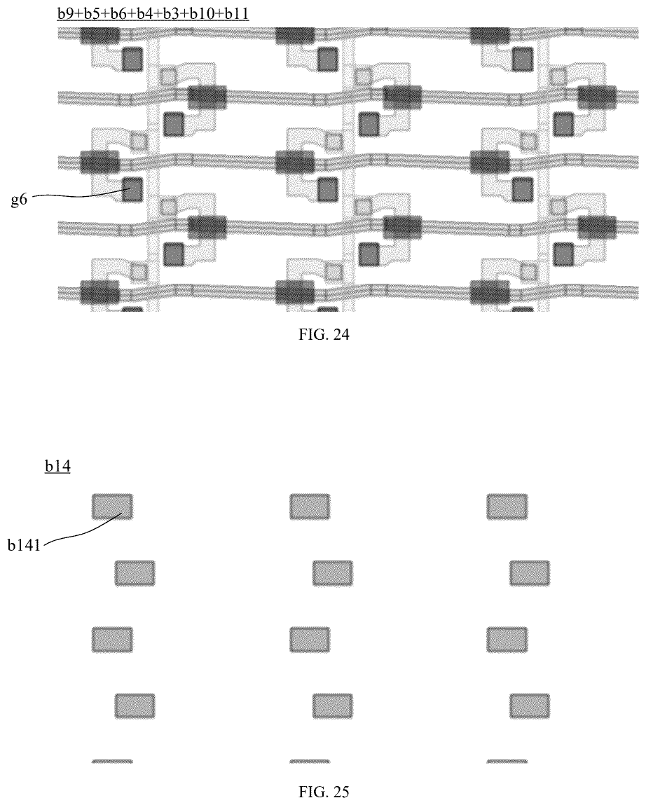

FIG. 23 is a partial schematic diagram of a first passivation layer and a first planarization layer according to some embodiments of the present disclosure. FIG. 24 is a partially superimposed schematic diagram of a source-drain layer, a buffer layer, an active layer, a transparent electrode layer, a gate layer, a first passivation layer, and a first planarization layer according to some embodiments of the present disclosure. Combined with FIG. 23 and FIG. 24, the first passivation layer b10 and the first planarization layer b11 are each provided with a sixth via g6. The sixth via g6 is configured to expose the drain region b61b, and the sixth via g6 is used for a subsequent electrode transfer pattern b141 to be connected to the drain region b61b of the active pattern b61.

The first passivation layer b10 and the first planarization layer b11 have the same film layer structure, and thus are only illustrated by FIG. 23 and FIG. 24. Moreover, in order to facilitate the illustration of the respective sixth vias g6 of the first passivation layer b10 and the first planarization layer b11, a fill pattern is used in FIG. 23 and FIG. 24 to represent the sixth vias g6. Other regions not drawn with a fill pattern are used to represent the regions where the first passivation layer b10 and the first planarization layer b11 are made of a solid material.

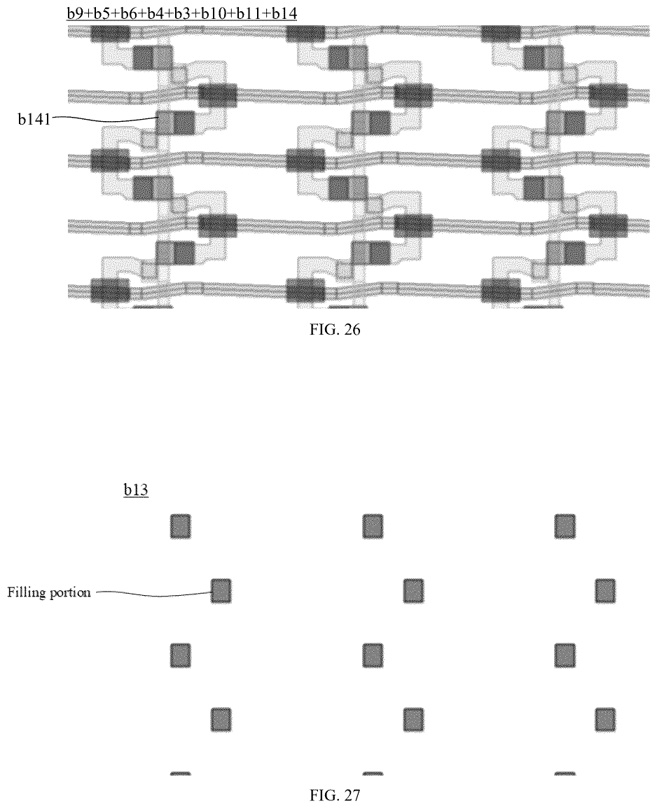

FIG. 25 is a partial schematic diagram of an electrode transfer layer according to some embodiments of the present disclosure. FIG. 26 is a partially superimposed schematic diagram of a source-drain layer, a buffer layer, an active layer, a transparent electrode layer, a gate layer, a first passivation layer, a first planarization layer, and an electrode transfer layer according to some embodiments of the present disclosure. Combined with FIG. 25 and FIG. 26, the electrode transfer layer b14 includes a plurality of electrode transfer patterns b141, a fifth portion b141a of each of the electrode transfer patterns b141 is connected to the drain region b61b of the active pattern b61 through the sixth via g6. And the electrode transfer patterns b141 also have a sixth portion b141b that is integrally structured with the fifth portion b141a, which is disposed on a side of the first planarization layer b11 away from the first substrate 1011.

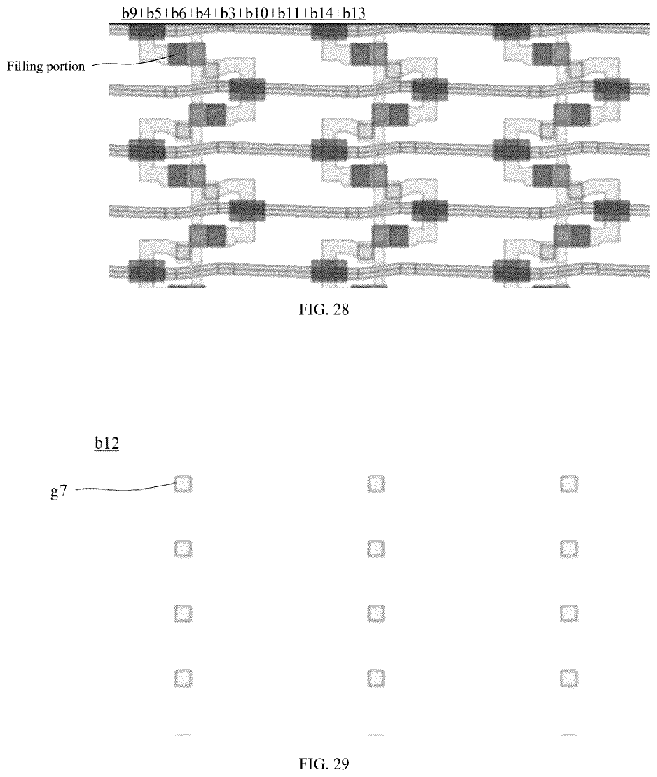

FIG. 27 is a partial schematic diagram of a second planarization layer according to some embodiments of the present disclosure. FIG. 28 is a partially superimposed schematic diagram of a source-drain layer, a buffer layer, an active layer, a transparent electrode layer, a gate layer, a first passivation layer, a first planarization layer, an electrode transfer layer, and a second planarization layer according to some embodiments of the present disclosure. Combined with FIG. 27 and FIG. 28, the second planarization layer b13 includes at least a filling portion for filling into the sixth via g6. For example, only the portion filled into the sixth via g6 is shown in FIG. 27 and FIG. 28 using a filling pattern, and the remaining unpatterned regions are used to indicate regions without solid material. In addition, the second planarization layer b13 may also be disposed in other regions, which is not limited in the embodiments of the present disclosure.

As the second planarization layer b13 is disposed within the sixth via g6, the disposition of the sixth via g6 can be flattened, which in turn ensures that the surface of the pixel electrode layer b1 close to the first substrate 1011 is a flat surface.

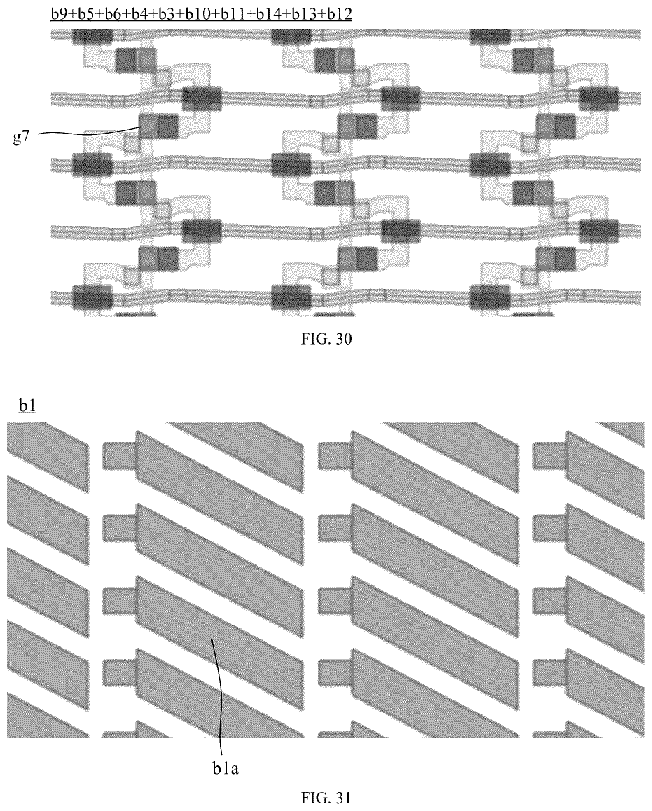

FIG. 29 is a partial schematic diagram of a second passivation layer according to some embodiments of the present disclosure. FIG. 30 is a partially superimposed schematic diagram of a source-drain layer, a buffer layer, an active layer, a transparent electrode layer, a gate layer, a first passivation layer, a first planarization layer, an electrode transfer layer, a second planarization layer, and a second passivation layer according to some embodiments of the present disclosure. Combined with FIG. 29 and FIG. 30, the second passivation layer b12 is provided with a seventh via g7. The seventh via g7 is used for a subsequent pixel electrode b1a to be connected to the electrode transfer pattern b141.

In order to facilitate the illustration of the respective seventh vias g7 of the second passivation layer b12, a fill pattern is used in FIG. 29 and FIG. 30 to represent the seventh vias g7. Other regions not drawn with a fill pattern are used to represent regions where the second passivation layer b12 is made of a solid material.

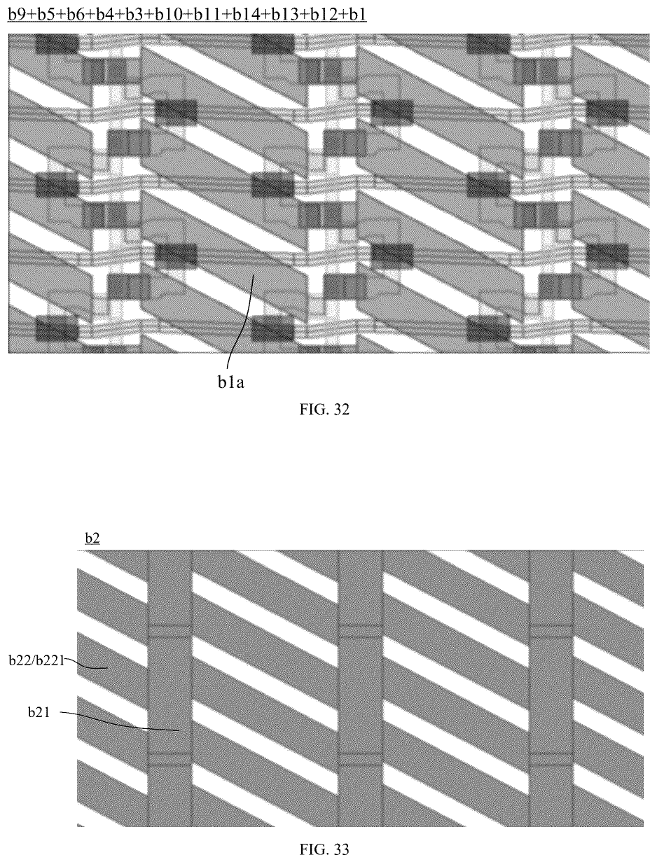

FIG. 31 is a partial schematic diagram of a pixel electrode layer according to some embodiments of the present disclosure. FIG. 32 is a partially superimposed schematic diagram of a source-drain layer, a buffer layer, an active layer, a transparent electrode layer, a gate layer, a first passivation layer, a first planarization layer, an electrode transfer layer, a second planarization layer, a second passivation layer, and a pixel electrode layer according to some embodiments of the present disclosure. Combined with FIG. 31 and FIG. 32, the pixel electrode layer b1 includes a plurality of pixel electrode patterns, and an orthographic projection of each pixel electrode pattern on the first substrate 1011 is in a strip shape, and an extension direction of the pixel electrode b1a intersects both the first direction A1 and the second direction A2. Moreover, each pixel electrode b1a may be connected to the electrode transfer pattern b141 through the seventh via g7.

The third passivation layer b17 may be formed on the above-described pixel electrode layer b1 for insulating the above-described pixel electrode layer b1 from the subsequently formed common electrode layer b2.

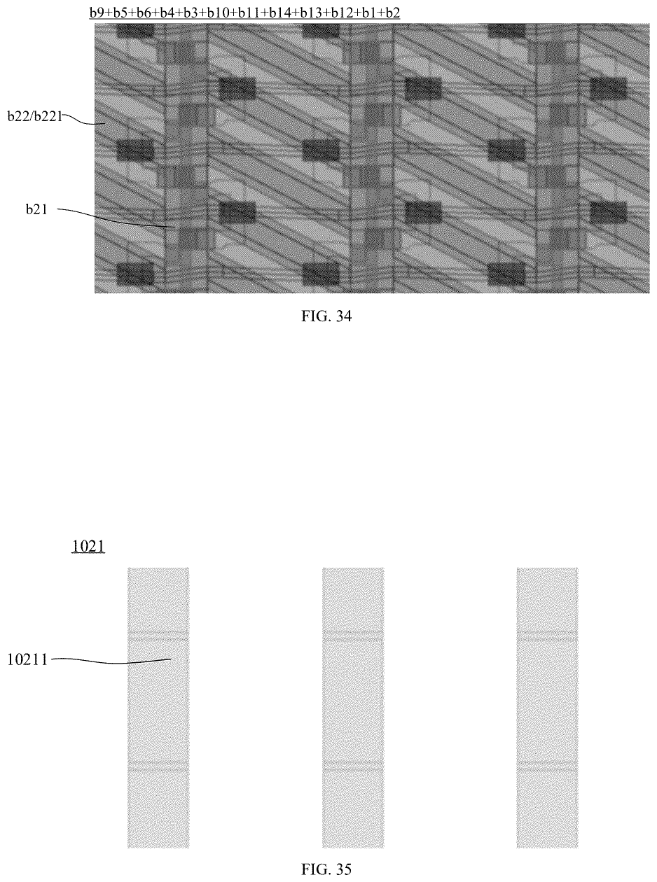

FIG. 33 is a partial schematic diagram of a common electrode layer according to some embodiments of the present disclosure. FIG. 34 is a partially superimposed schematic diagram of a source-drain layer, a buffer layer, an active layer, a transparent electrode layer, a gate layer, a first passivation layer, a first planarization layer, an electrode transfer layer, a second planarization layer, a second passivation layer, a pixel electrode layer, and a common electrode layer according to some embodiments of the present disclosure. Combined with FIG. 33 and FIG. 34, the common electrode layer b2 includes a plurality of first electrode portions b21 arranged in the second direction A2 and a plurality of second electrode portions b22 arranged in the second direction A2. The plurality of first electrode portions b21 and the plurality of second electrode portions b22 are staggered.

An orthographic projection of the first electrode portion b21 on the first substrate 1011 covers an orthographic projection of one data line 1013 on the first substrate 1011. The second electrode portion b22 includes a plurality of common electrode patterns b221 arranged at intervals in the first direction A1. One end of each common electrode pattern b221 is connected to one of the two adjacent first electrode portions b21, and the other end is connected to the other of the two adjacent first electrode portions b21.

The orthographic projection of each common electrode pattern b221 on the first substrate 1011 is in a strip shape, and the extension direction of the common electrode pattern b221 is parallel to the extension direction of the pixel electrode b1a. The orthographic projection of the common electrode pattern b221 on the first substrate 1011 at least partially overlaps with the orthographic projection of the pixel electrode b1a on the first substrate 1011.

In some embodiments, the length of the overlapping region of the common electrode pattern b221 and the pixel electrode b1a in a direction perpendicular to the extension direction of either the common electrode pattern b221 or the pixel electrode b1a is greater than or equal to 0.5 μm, such as 1 μm. Thereby, the common electrode pattern b221 and the pixel electrode b1a can be facilitated to generate an electric field for driving the liquid crystal molecules in the liquid crystal layer 103 to deflect.

Referring to FIG. 33, the first electrode portion b21 is of an integral structure, and a plurality of common electrode patterns b221 of the second electrode portion b22 are connected through the first electrode portion b21. Thereby, the common electrode layer b2 transmits the common electrode signal.

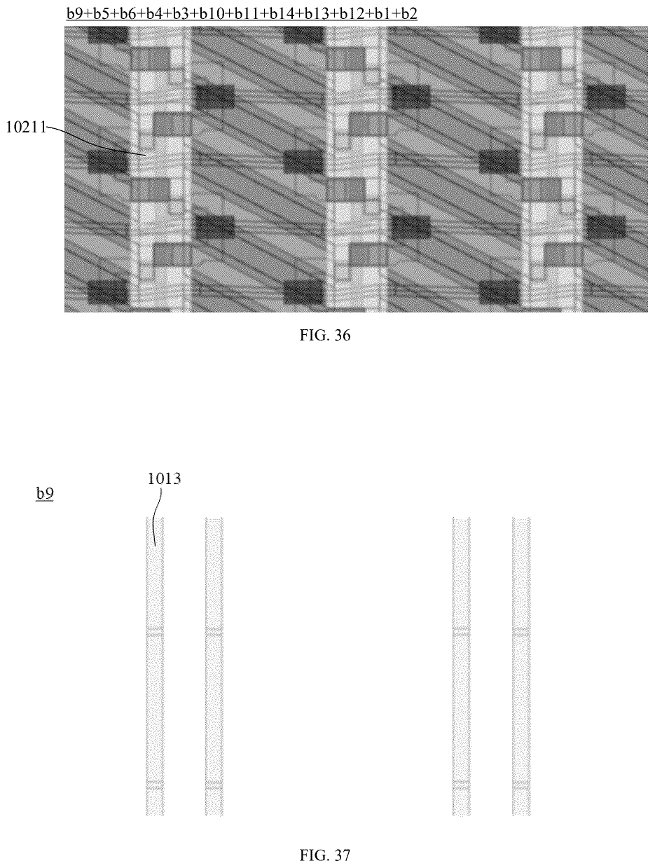

FIG. 35 is a partial schematic diagram of a black matrix layer according to some embodiments of the present disclosure. FIG. 36 is a partially superimposed schematic diagram of a source-drain layer, a buffer layer, an active layer, a transparent electrode layer, a gate layer, a first passivation layer, a first planarization layer, an electrode transfer layer, a second planarization layer, a second passivation layer, a pixel electrode layer, a common electrode layer, and a black matrix layer according to some embodiments of the present disclosure. As can be seen in conjunction with FIG. 35 and FIG. 36, the black matrix layer 1021 includes a plurality of black matrix structures 10211. An orthographic projection of each black matrix structure 10211 on the first substrate 1011 covers the orthographic projection of the first electrode portion b21 on the first substrate 1011.

In some embodiments, the orthographic projection of the black matrix structure 10211 on the first substrate 1011 covers the orthographic projection of one data line 1013 on the first substrate 1011, and the distance between an edge of the orthographic projection of the black matrix structure 10211 on the first substrate 1011 and an edge of the orthographic projection of the source-drain pattern on the first substrate 1011 is greater than or equal to 1 μm, thereby ensuring that the black matrix structure 10211 completely covers the data line 1013 and the source-drain pattern to avoid affecting the display of the display panel 10.

Further, taking the array substrate 101 shown in FIG. 13 as an example, each film layer of the array substrate 101 is briefly described below in terms of individual single layers as well as step-by-step stacking manner.

FIG. 37 is a partial schematic diagram of a source-drain layer according to some embodiments of the present disclosure. As can be seen with reference to FIG. 37, the source-drain layer b9 includes a plurality of data lines 1013, the source-drain pattern (not shown in FIG. 12) and the data line 1013 are of an integral structure, and the data line 1013 and the source-drain pattern are in one line.

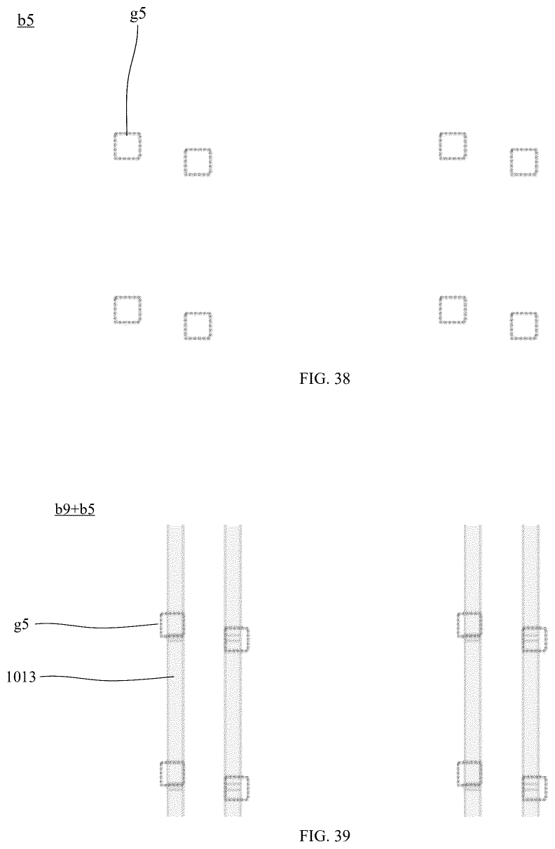

FIG. 38 is a partial schematic diagram of a buffer layer according to some embodiments of the present disclosure. FIG. 39 is a partially superimposed schematic diagram of a source-drain layer and a buffer layer according to some embodiments of the present disclosure. Combined with FIG. 38 and FIG. 39, the buffer layer b5 may be provided with a fifth via g5 for exposing at least a portion of the source-drain pattern, and the fifth via g5 for a subsequent active pattern b61 to be connected to the source-drain pattern. In order to facilitate the illustration of individual fifth vias g5 of the buffer layer b5, a fill pattern is used in FIG. 38 and FIG. 39 to represent the fifth vias g5. Other regions not drawn with a fill pattern are used to represent regions where the buffer layer b5 is made of a solid material.

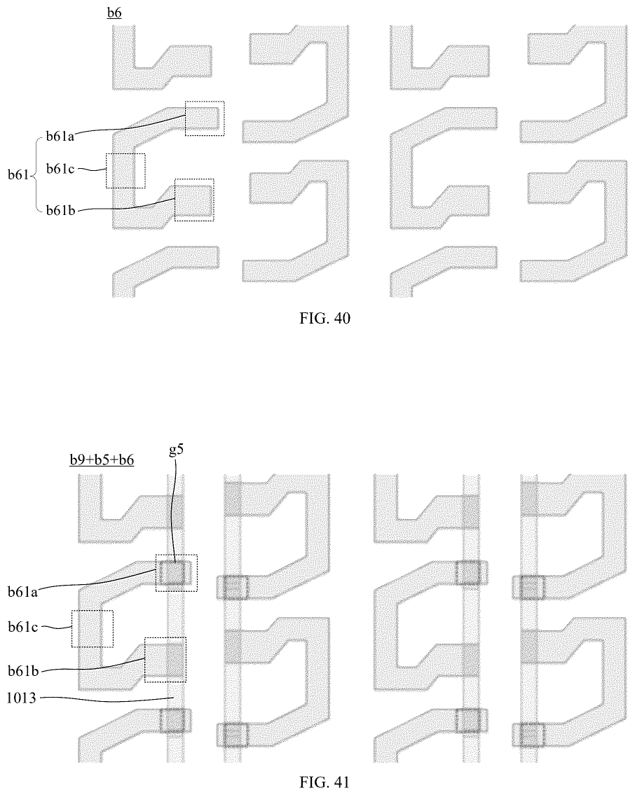

FIG. 40 is a partial schematic diagram of an active layer according to some embodiments of the present disclosure. FIG. 41 is a partially superimposed schematic diagram of a source-drain layer, a buffer layer, and an active layer according to some embodiments of the present disclosure. Combined with FIG. 40 and FIG. 41, the active layer b6 includes a plurality of active patterns b61, for the plurality of active patterns b61 corresponding to the two data lines 1013, a portion of the active patterns b61 are disposed on a first side of the two data lines 1013, and another portion of the active patterns b61 are disposed on a second side of the two data lines 1013.

Each active pattern b61 and one of the two data lines 1013 closest to the active pattern b61 are connected through a fifth via g5 in the buffer layer b5.

In the embodiments of the present disclosure, the display panel 10 includes a gate insulating layer b7 disposed on the side of the active layer b6 away from the first substrate 1011 for insulating the active layer b6 from the subsequently formed gate layer b3. The gate insulating layer b7 may be a film layer covering the entire layer, which is no longer illustrated in the accompanying drawings.

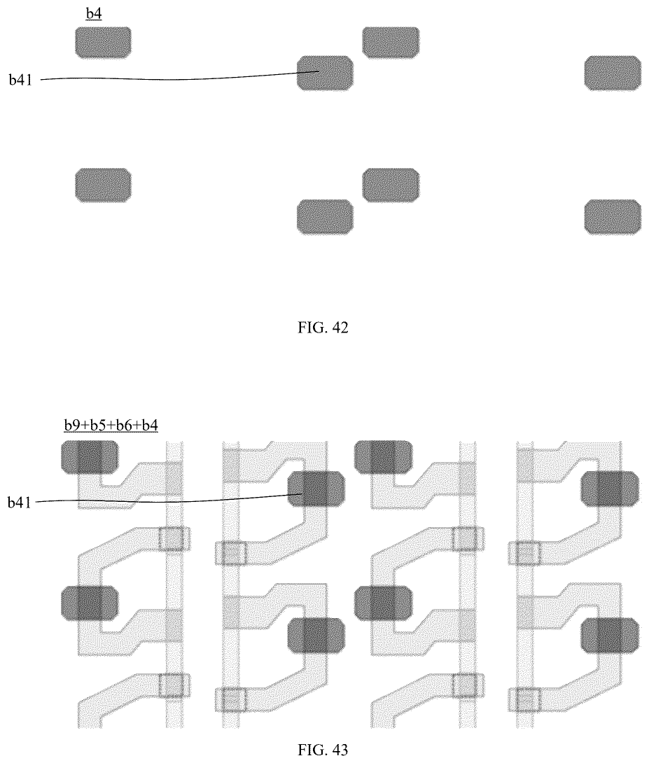

FIG. 42 is a partial schematic diagram of a transparent electrode layer according to some embodiments of the present disclosure. FIG. 43 is a partially superimposed schematic diagram of a source-drain layer, a buffer layer, an active layer, and a transparent electrode layer according to some embodiments of the present disclosure. Combined with FIG. 42 and FIG. 43, the transparent electrode layer b4 includes a plurality of transparent electrode patterns b41. An orthographic projection of the transparent electrode pattern b41 on the first substrate partially overlaps with an orthographic projection of the active pattern b61 on the first substrate.

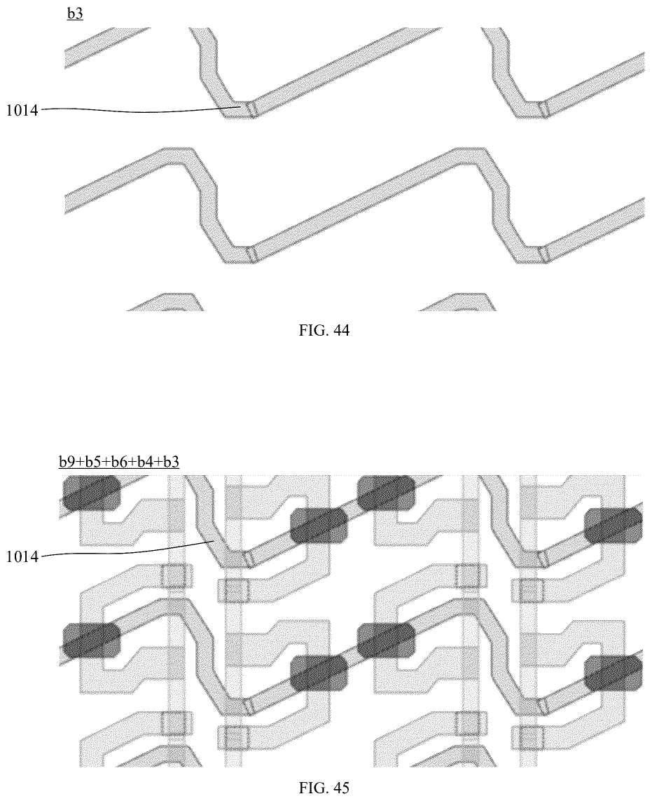

FIG. 44 is a partial schematic diagram of a gate layer according to some embodiments of the present disclosure. FIG. 45 is a partially superimposed schematic diagram of a source-drain layer, a buffer layer, an active layer, a transparent electrode layer, and a gate layer according to some embodiments of the present disclosure. Combined with FIG. 44 and FIG. 45, the gate layer b3 includes a plurality of gate lines 1014. An orthographic projection of each gate line 1014 on the first substrate 1011 partially overlaps with an orthographic projection of the transparent electrode pattern b41 on the first substrate 1011. The gate lines 1014 and the transparent electrode pattern b41 are directly structured for forming the channel region b61c of the switching transistor.

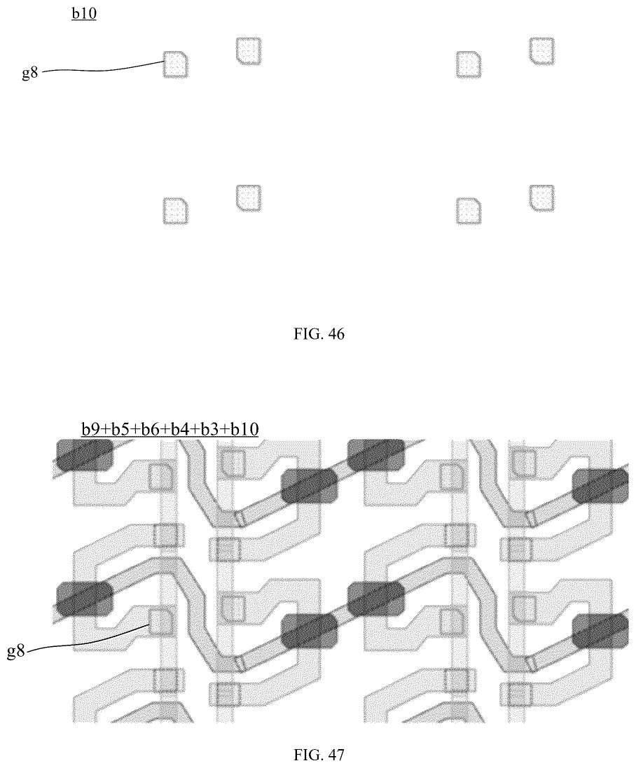

FIG. 46 is a partial schematic diagram of a first passivation layer according to some embodiments of the present disclosure. FIG. 47 is a partially superimposed schematic diagram of a source-drain layer, a buffer layer, an active layer, a transparent electrode layer, a gate layer, and a first passivation layer according to some embodiments of the present disclosure. Combined with FIG. 46 and FIG. 47, the first passivation layer b10 is provided with an eighth via g8. The eighth via g8 is configured to expose the drain region b61b, and the eighth via g8 is configured for a subsequent electrode transfer pattern b141 to be connected to the drain region b61b of the active pattern b61.

In order to facilitate the illustration of the respective eighth vias g8 of the first passivation layer b10, a fill pattern is used in FIG. 46 and FIG. 47 to represent the eighth vias g8. Other regions not drawn with a fill pattern are used to represent regions where the first passivation layer b10 is made of a solid material.

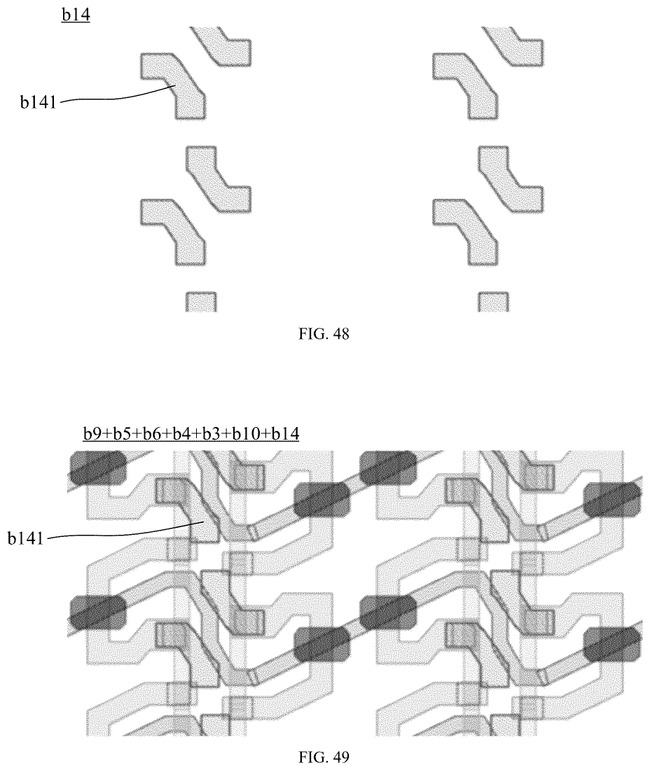

FIG. 48 is a partial schematic diagram of an electrode transfer layer according to some embodiments of the present disclosure. FIG. 49 is a partially superimposed schematic diagram of a source-drain layer, a buffer layer, an active layer, a transparent electrode layer, a gate layer, a first passivation layer, and an electrode transfer layer according to some embodiments of the present disclosure. Combined with FIG. 48 and FIG. 49, the electrode transfer layer b14 is connected to the drain region b61b of the active pattern b61 through the eighth via g8.

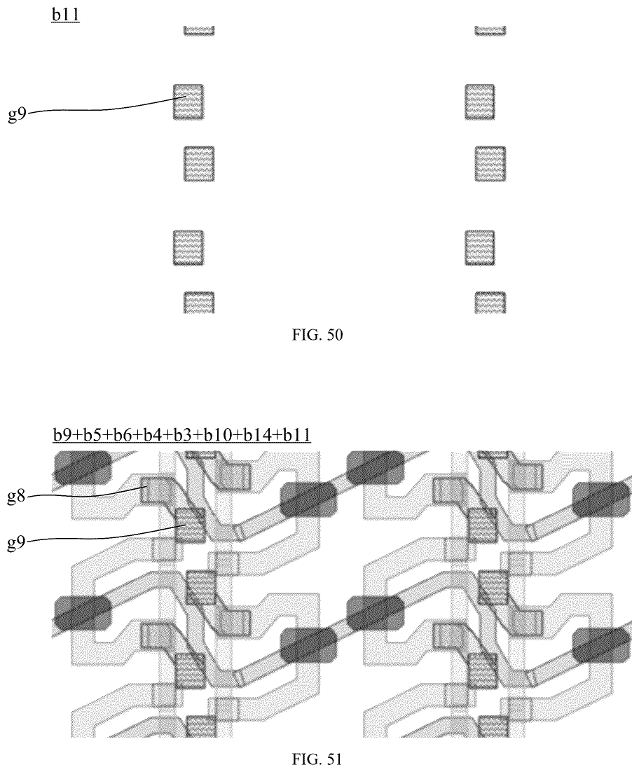

FIG. 50 is a partial schematic diagram of a first planarization layer according to some embodiments of the present disclosure. FIG. 51 is a partially superimposed schematic diagram of a source-drain layer, a buffer layer, an active layer, a transparent electrode layer, a gate layer, a first passivation layer, an electrode transfer layer, and a first planarization layer according to some embodiments of the present disclosure. As can be seen in conjunction with FIG. 50 and FIG. 51, the first planarization layer b11 is provided with a ninth via g9. The ninth via g9 is configured to expose a portion of the electrode transfer pattern b141. The ninth via g9 is configured for a subsequent pixel electrode b1a to be connected to the electrode transfer pattern b141.

In order to facilitate the illustration of the individual ninth vias g9 of the first planarization layer b11, a fill pattern is used in FIG. 50 and FIG. 51 to represent the ninth vias g9. Other regions that are not drawn with a fill pattern are used to represent regions of the first planarization layer b11 is made of a solid material.

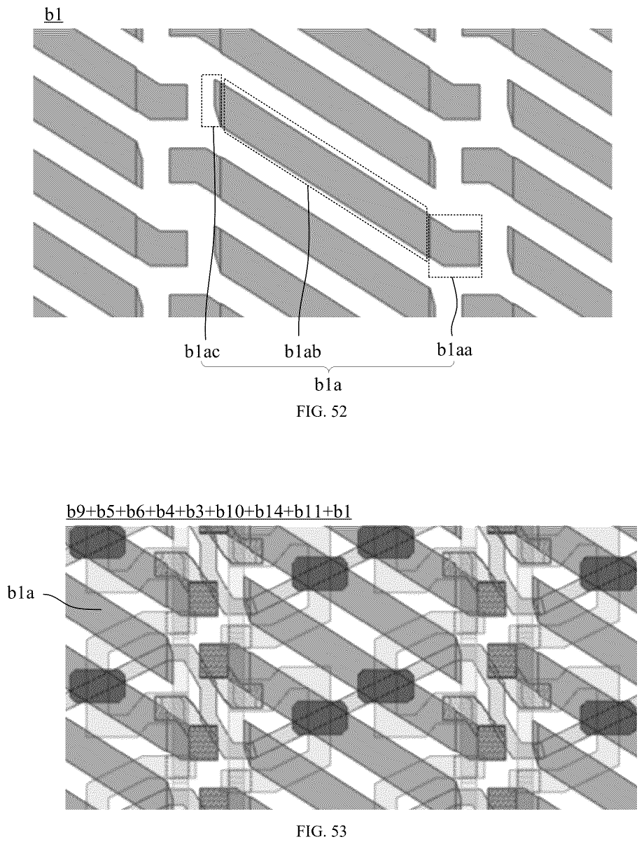

FIG. 52 is a partial schematic diagram of a pixel electrode layer according to some embodiments of the present disclosure. FIG. 53 is a partially superimposed schematic diagram of a source-drain layer, a buffer layer, an active layer, a transparent electrode layer, a gate layer, a first passivation layer, an electrode transfer layer, a first planarization layer, and a pixel electrode layer according to some embodiments of the present disclosure. Combined with FIG. 52 and FIG. 53, the pixel electrode layer b1 includes a plurality of pixel electrode patterns. An orthographic projection of each of the pixel electrode patterns b1a on the first substrate 1011 is in a strip shape, and an extension direction of the pixel electrode b1a intersects both the first direction A1 and the second direction A2. In addition, each pixel electrode b1a may be connected to the electrode transfer pattern b141 through the ninth via g9.

The second passivation layer b12 may be formed on the above-described pixel electrode layer b1 for insulating the above-described pixel electrode layer b1 from the subsequently formed common electrode layer b2.

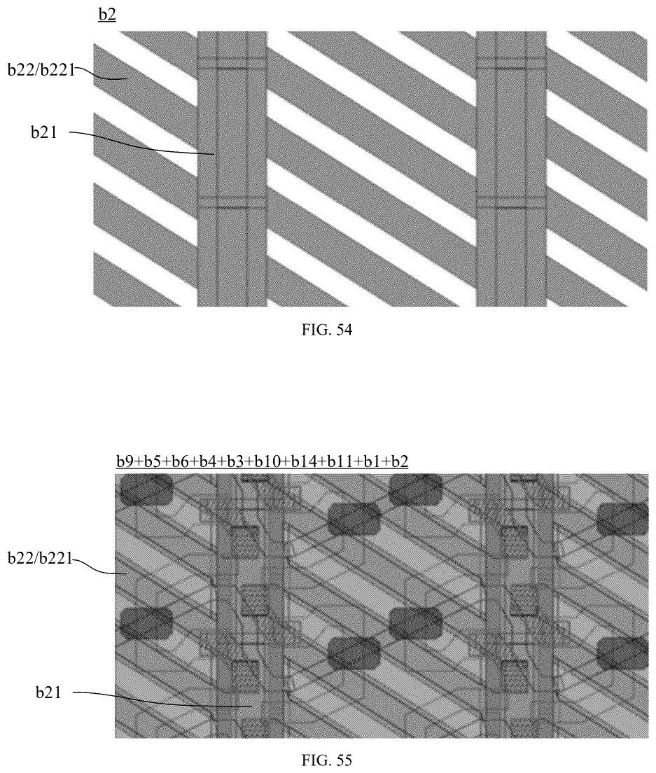

FIG. 54 is a partial schematic diagram of a common electrode layer according to some embodiments of the present disclosure. FIG. 55 is a partially superimposed schematic diagram of a source-drain layer, a buffer layer, an active layer, a transparent electrode layer, a gate layer, a first passivation layer, an electrode transfer layer, a first planarization layer, a pixel electrode layer, a second passivation layer, and a common electrode layer according to some embodiments of the present disclosure. Combined with FIG. 54 and FIG. 55, the common electrode layer b2 includes a plurality of first electrode portions b21 arranged in the second direction A2 and a plurality of second electrode portions b22 arranged in the second direction A2. The plurality of first electrode portions b21 and the plurality of second electrode portions b22 are staggered.

An orthographic projection of the first electrode portion b21 on the first substrate 1011 covers orthographic projections of the two data lines 1013 on the first substrate 1011. The second electrode portion b22 includes a plurality of common electrode patterns b221 arranged at intervals in the first direction A1. One end of each common electrode pattern b221 is connected to one of the two adjacent first electrode portions b21, and the other end of each common electrode pattern b221 is connected to the other of the two adjacent first electrode portions b21.

The orthographic projection of each common electrode pattern b221 on the first substrate 1011 is in a strip shape, and the extension direction of the common electrode pattern b221 is parallel to the extension direction of the pixel electrode b1a. The orthographic projection of the common electrode pattern b221 on the first substrate 1011 at least partially overlaps with the orthographic projection of the pixel electrode b1a on the first substrate 1011.

In some embodiments, the length of the overlapping region of the common electrode pattern b221 and the pixel electrode b1a in the direction perpendicular to the extension direction of either the common electrode pattern b221 or the pixel electrode b1a is greater than or equal to 0.5 μm, such as 1 μm. Thereby, the common electrode pattern b221 and the pixel electrode b1a can be facilitated to generate an electric field for driving the liquid crystal molecules in the liquid crystal layer 103 to deflect.

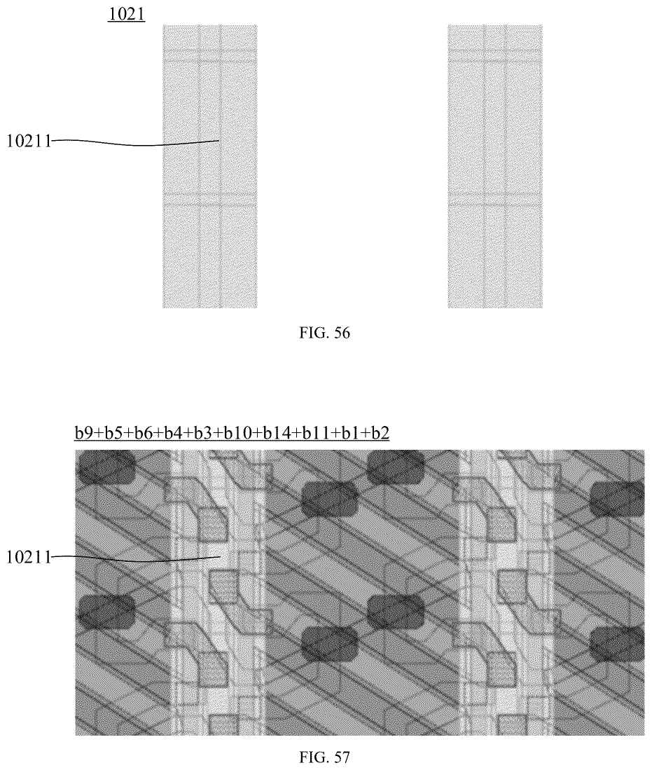

FIG. 56 is a partial schematic diagram of a black matrix layer according to some embodiments of the present disclosure. FIG. 57 is a partially superimposed schematic diagram of a source-drain layer, a buffer layer, an active layer, a transparent electrode layer, a gate layer, a first passivation layer, an electrode transfer layer, a first planarization layer, a pixel electrode layer, a second passivation layer, a common electrode layer, and a black matrix layer according to some embodiments of the present disclosure. Combined with FIG. 56 and FIG. 57, it can be seen that the black matrix layer 1021 includes a plurality of black matrix structures 10211. An orthographic projection of each of the black matrix structures 10211 on the first substrate 1011 covers the orthographic projection of the first electrode portion b21 on the first substrate 1011.

In some embodiments, the orthographic projection of the black matrix structure 10211 on the first substrate 1011 covers the orthographic projections of the two data lines 1013 on the first substrate 1011, and a distance between an edge of the orthographic projection of the black matrix structure 10211 on the first substrate 1011 and an edge of the orthographic projections of the two data lines 1013 on the first substrate 1011 is greater than or equal to 1 μm, thereby ensuring that the black matrix structure 10211 completely covers the two data lines 1013 to avoid that the data lines 1013 from affecting the display of the display panel 10.

In the embodiments of the present disclosure, the pixel electrode b1a has a first pixel portion b1aa, a second pixel portion blab, and a third pixel portion b1ac. The first pixel portion b1aa, the second pixel portion blab, and the third pixel portion b1ac are of an integral structure. An orthographic projection of the first pixel portion b1aa on the first substrate 1011 is located within an orthographic projection of the first target black matrix structure on the first substrate 1011, and the first pixel portion b1aa is used for connecting with the electrode transfer pattern b141. An orthographic projection of the second pixel portion blab on the first substrate 1011 is located between the first target black matrix structure and a second target black matrix structure. An orthographic projection of the third pixel portion b1ac on the first substrate 1011 is located within an orthographic projection of the second target black matrix structure on the first substrate 1011. The first target black matrix structure and the second target black matrix structure are two black matrix structures 10211 that are adjacent in the second direction A2.

In some embodiments, the length of the first pixel portion b1aa in the second direction A2, and the length of the third pixel portion b1ac in the second direction A2 are both greater than or equal to 1 μm. That is, the length of the portion of both ends of the pixel electrodes b1a that are covered by the black matrix structure 10211 in the second direction A2 are both greater than or equal to 1 μm. Thereby, light leakage from the edges of the pixel electrodes b1a can be avoided, and the display effect of the display panel 10 is ensured.

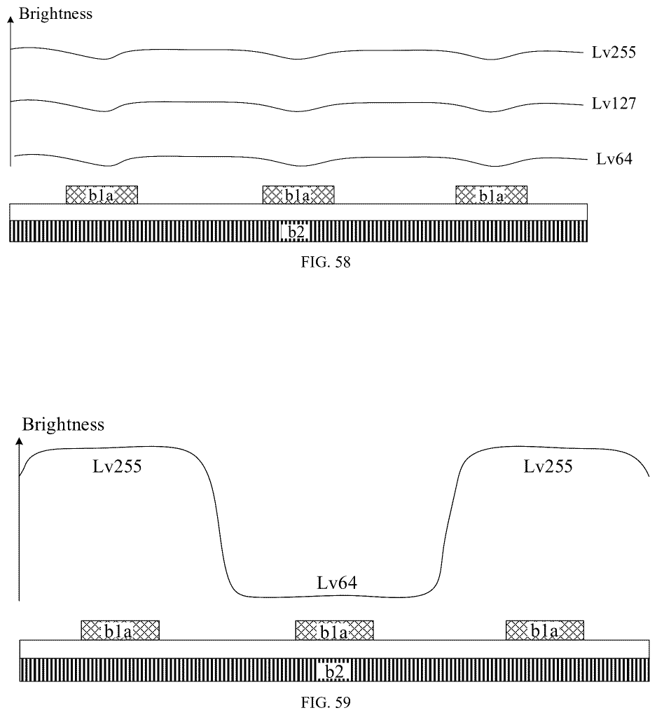

In the embodiments of the present disclosure, the array substrate 101 included in the display panel 10 is designed as described above, which can enable the display panel 10 to realize continuous light emission at each gray scale, with the effect shown in FIG. 58. In the three cases where the gray scale is Lv64, Lv127, and Lv255, the brightness curve is approximately a straight line, i.e., the brightness where different pixel electrodes are disposed is approximately the same, which enables the display panel 10 to realize continuous light emission.

And, referring to FIG. 59, in the case that the gray scale of the adjacent pixel electrodes b1a is different, the brightness where the adjacent pixel electrodes b1a in the display panel 10 are disposed is different. That is, the brightness between adjacent sub-pixels does not affect each other.

FIGS. 58 and 59 are only used to illustrate the brightness relationship where different pixel electrodes b1a in the display panel 10 are disposed, and are not used to represent the film layer relationship of the actual product.

In the embodiments of the present disclosure, referring to FIG. 1, the display panel 10 further includes a lens layer 104 disposed on a side of the color filter substrate 102 away from the array substrate 101. The lens layer 104 includes a plurality of lens structures 1041. A surface of each of the lens structures 1041 away from the array substrate 101 is curved.

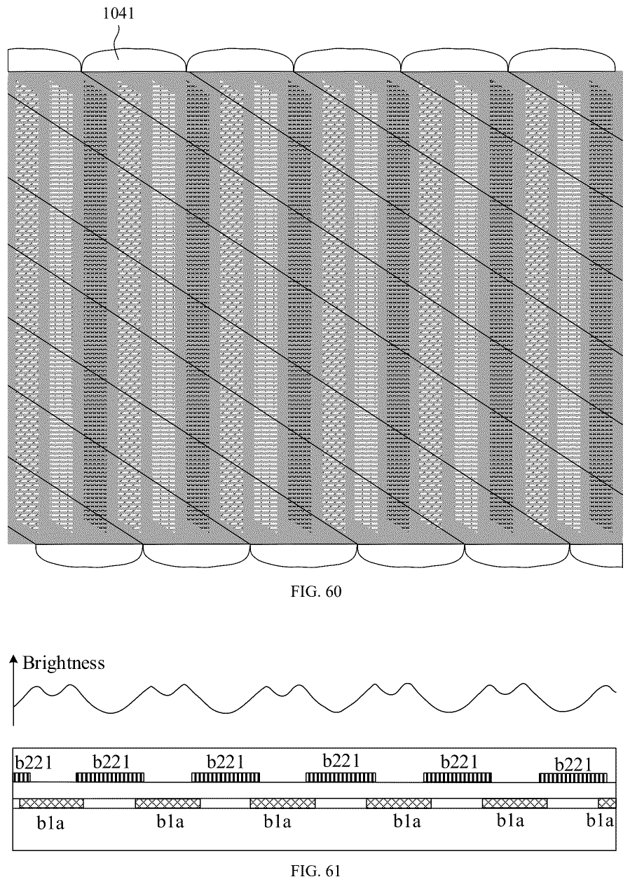

FIG. 60 is a partial schematic diagram of a display panel according to some embodiments of the present disclosure. Referring to FIG. 60, an orthographic projection of the lens structure 1041 on the array substrate 101 is in a strip shape. An extension direction of the lens structure 1041 in FIG. 60 is parallel to the extension direction of the pixel electrode b1a. That is, the extension direction of the lens structure 1041 intersects the first direction A1, the second direction A2, and the third direction A3.

The lens structure 1041 and the pixel electrodes b1a included in the array substrate 101 form a display unit of the display panel 10, which can form a multi-directional 3D display effect, and is capable of fulfilling a 3D display screen of a horizontal or vertical screen. At the same time, both the pixel electrodes b1a and the lens structure 1041 in the display unit are capable of spanning a plurality of opening regions 10a, and thus a continuous display screen can be formed, realizing a display effect similar to continuous light emission.

For the scheme in which the extension direction of the lens structure 1041 is parallel to the extension direction of the pixel electrode b1a, with reference to FIG. 61, the display panel 10 has an uneven distribution of internal brightness of the sub-pixels when the sub-pixels are lit during the display process, and the distribution of the electric field lines in the boundary position of the common electrode pattern b221 is more dense, which in turn can result in the brightness having a peak at the boundary position of the common electrode pattern b221.

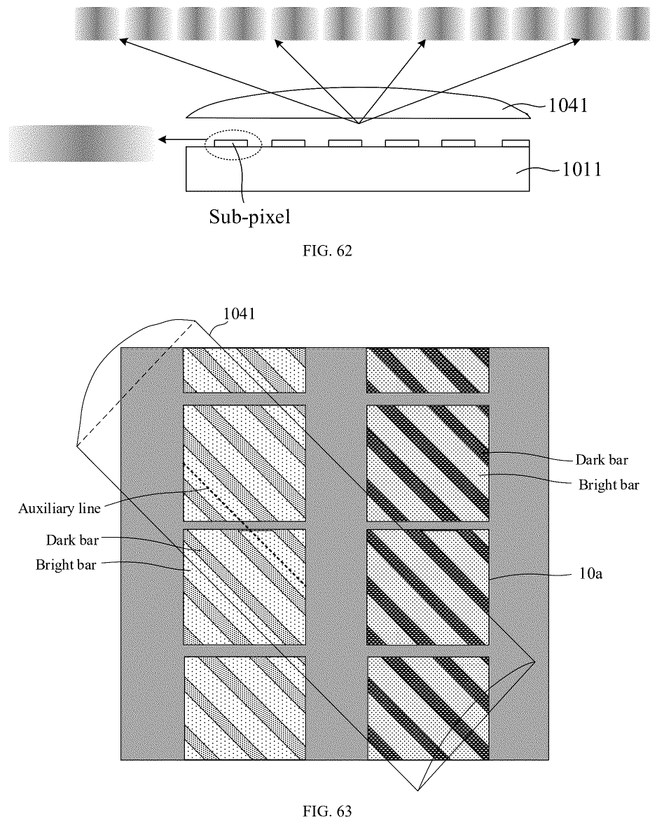

The internal brightness unevenness of individual sub-pixels usually has no effect on 2D display, but referring to FIG. 62, in 3D display, such micro-uniformity is amplified by the lens structure 1041, and moiré is formed when it is projected to different angles, and the display effect of the display panel 10 is poorer.

Referring to FIG. 63, the reason that the scheme in which the extension direction of the lens structure 1041 is parallel to the extension direction of the pixel electrode b1a produces moiré is that an auxiliary line of the lens structure 1041 (the auxiliary line is a line parallel to any position of the extension direction of the lens structure 1041) will be parallel to the bright and dark bars of the pixel electrode b1a, which will in turn cause light beams of the pixels 1012 at the position of the auxiliary line to be projected in the same direction. As a result, the user will sometimes see the bright bars and sometimes see the dark bars when viewing, which will lead to variations in brightness and darkness at different viewing angles, thus creating moiré. The bright and dark bars of the pixel electrode b1a are parallel to the extension direction of the pixel electrode b1a. The disposition of the pixel electrode b1a constitutes the bright bar, and the gap between adjacent pixel electrodes b1a constitutes the dark bar.

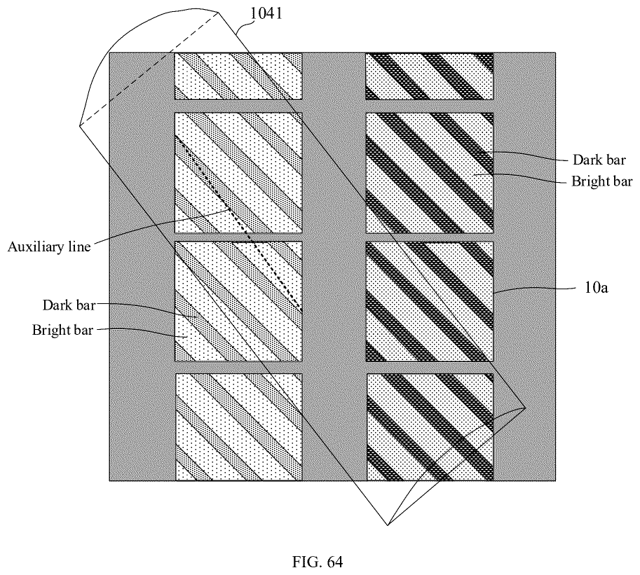

For the above reasons, referring to FIG. 64, the extension direction of the lens structure 1041 intersects the extension direction of the pixel electrode b1a, such that the auxiliary line of the lens structure 1041 can span both the light and dark bars as much as possible, thereby making the brightness perceived by the user when viewed at different positions as much as possible the same, thus solving the problem of moiré caused by the uneven light emission of the sub-pixel.

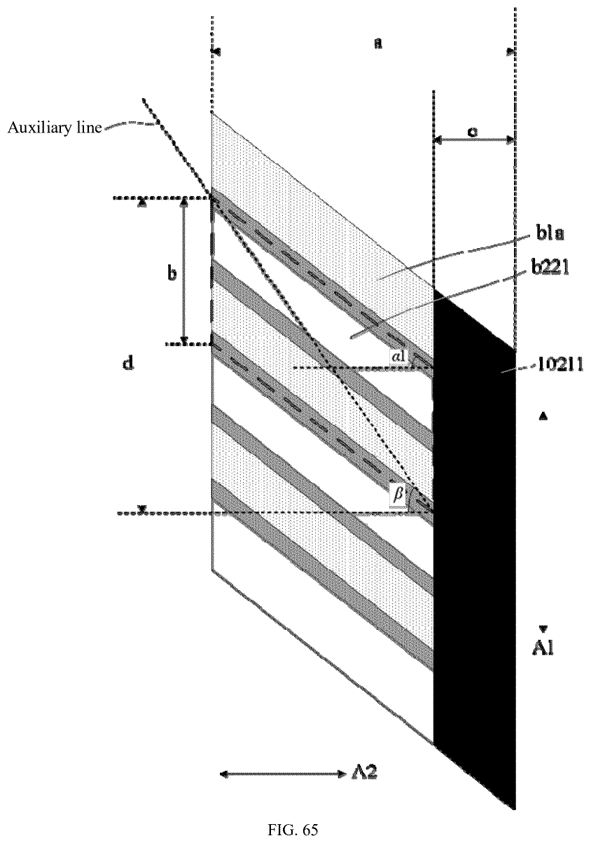

Further, referring to FIG. 65, in order to completely avoid the moiré problem, the first condition to be satisfied is that the length of the portion of the lens structure 1041 disposed in the opening region 10a in the first direction A1 is equal to the maximum distance between two ends of the sub-pixel in the first direction A1. That is, the auxiliary line of the lens structure 1041 passes through both a first target point and a second target point of the array substrate 101. The first target point and the second target point are diagonal points of two of the four corner points of the sub-pixel, and a distance between these two diagonal points is greater than a distance between the other two diagonal points.

In the first condition, the first direction A1 is a pixel column direction of the display panel 10, the second direction A2 is a pixel row direction of the display panel 10, and a first conditional angle α1 between the extension direction of the pixel electrode b1a and the second direction A2 is satisfied:

$$tan α 1 = \frac{d - b}{a - c} \qquad Formula ( 3 )$$

An angle between the extension direction of the lens structure 1041 and the second direction A2 is satisfied:

$$tan β = \frac{d}{a - c} \qquad Formula ( 4 )$$

In the above formula (3) and formula (4), a is the length of the sub-pixel in the second direction A2, b is the length of the sub-pixel in the first direction A1, c is the length of the black matrix structure 10211 in the second direction A2, and d is the length of the portion of the lens structure 1041 that is disposed between two adjacent black matrix structures 10211 in the first direction A1. The length a of the sub-pixel in the second direction A2 is equal to the sum of the length of the black matrix structure 10211 in the second direction A2 and the distance between two adjacent black matrix structures 10211 in the second direction A2. The length c of the sub-pixel in the first direction A1 is equal to the sum of the length of the pixel electrode b1a in the first direction A1 and the distance between two adjacent pixel electrodes b1a in the first direction A1.

In the embodiments of the present disclosure, a, b, and c are known quantities in the above formula (3) and formula (4). By first determining the angle between the extension direction of the lens structure 1041 and the second direction A2, d is calculated according to formula (4). After that, a, b, c, and d can be substituted into formula (3) to calculate the first conditional angle. The angle β may be the angle α selected according to formula (2).

In the embodiments of the present disclosure, due to the tilted design of the pixel electrodes b1a, the design of the overlapping region of the different pixel electrodes b1a with the gate lines 1014 in the portion between the adjacent black matrix structures 10211 is different (the integral brightness caused by the gate line 1014 to the opening region 10a is different), which in turn generates light and dark moiré.

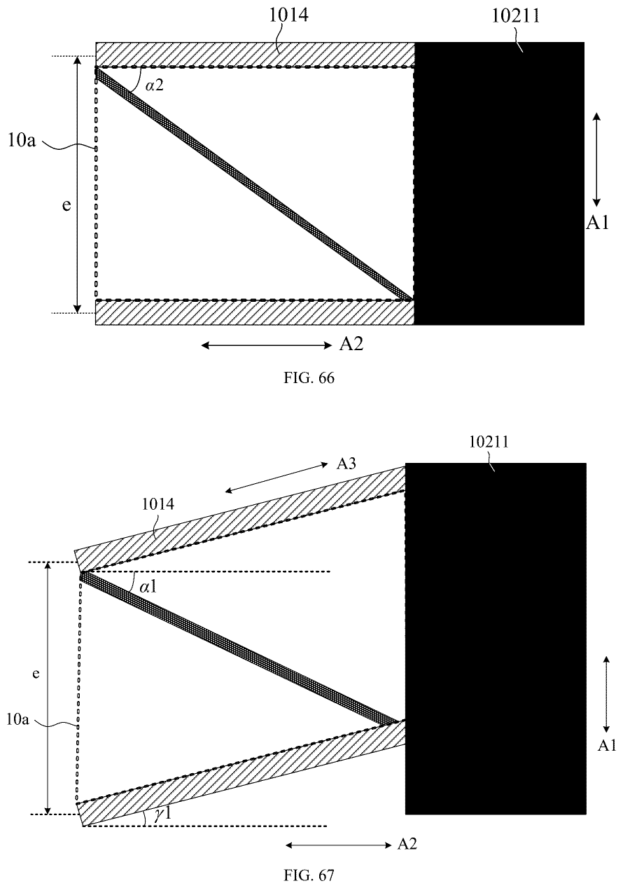

In option 1, referring to FIG. 66, in order to eliminate the effect of the gate line 1014, in the case that the extension direction of the gate line 1014 (the third direction A3) is the pixel row direction, the second condition to be satisfied is that the length of the portion of the pixel electrode b1a disposed between adjacent black matrix structures 10211 in the first direction A1 is equal to the distance of the adjacent gate lines 1014 in the first direction A1.

In the second condition, the second conditional angle α2 between the extension direction of the pixel electrode b1a and the second direction A2 is satisfied:

$$tan α 2 = \frac{e}{a - c} \qquad Formula ( 5 )$$

In the above-described formula (5), e is the distance between two adjacent gate lines 1014 in the first direction A1. In addition, in order to simultaneously eliminate the effects of the lens structure 1041 and the gate lines 1014 that produce moiré, both the above-described first condition and the second condition may be satisfied, and thus the angle between the extension direction of the pixel electrode b1a and the second direction A2 may be a common multiple of the first conditional angle and the second conditional angle.

In option two, referring to FIG. 67, in order to eliminate the effect of the gate line 1014, the extension direction of the gate line 1014 may be appropriately adjusted (i.e., the gate line 1014 may be set at an incline with respect to the pixel row direction). In some embodiments, a third condition satisfied after adjusting the extension direction of the gate line 1014 is that the sum of the length of the portion of the pixel electrode b1a disposed between the adjacent black matrix structure 10211 in the first direction A1, and the length of the portion of the gate line 1014 disposed between the adjacent black matrix structure 10211 in the first direction A1, is equal to the distance between the adjacent gate lines 1014 in the first direction A1. Moreover, the overlapping position of the pixel electrode b1a and the grating line 1014 is located at the junction of the black matrix structure 10211 and the opening region 10a.

Referring to FIG. 67, in the third condition, the third direction A3 and the second direction A2 intersect, and the third conditional angle γ1 between the third direction A3 and the second direction A2 is satisfied:

$$tan γ1 = \frac{e - ( a - c ) tan α 1}{a - c} \qquad Formula ( 6 )$$

In the formula (6), e is the distance between two adjacent gate lines 1014 in the first direction A1. Moreover, α1 in the formula (6) may be determined based on the first condition. Thus, by determining the third conditional angle γ1 by the formula (6), the influence of the lens structure 1041 and the gate line 1014 can be eliminated simultaneously to produce moiré.

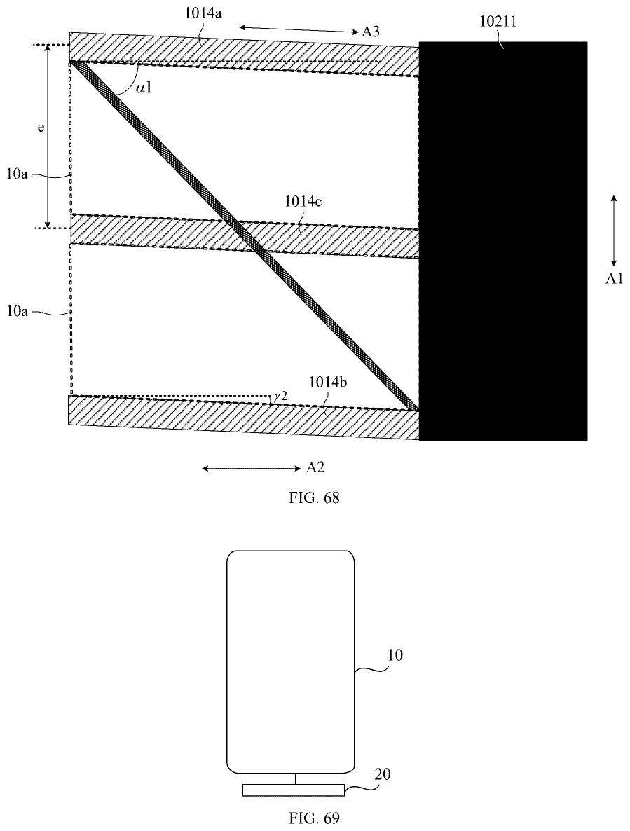

In option three, referring to FIG. 68, in the case that the first conditional angle α1 calculated based on the above-mentioned first condition can cause the pixel electrode b1a to span one gate line 1014. In turn, in order to eliminate the effect of the gate line 1014, a fourth condition to be satisfied is that the sum of the length of the portion of the pixel electrode b1a disposed between the adjacent black matrix structures 10211 in the first direction A1 and the length of the portion of the gate line 1014 disposed between the adjacent black matrix structure 10211 is equal to a distance between the first target grating line 1014a and the second target grating line 1014b in the first direction A1. A third target gate line 1014c is provided between the first target gate line 1014a and the second target gate line 1014b, which is the gate line 1014 spanned by the pixel electrode b1a. The orthographic projection of the pixel electrode b1a on the first substrate 1011 partially overlaps with the orthographic projection of the third target gate line 1014c on the first substrate 1011. Moreover, the overlapping position of the pixel electrode b1a and the gate line 1014 is disposed at the junction of the black matrix structure 10211 and the opening region 10a.

Referring to FIG. 68, in the fourth condition, the third direction A3 (the extension direction of the gate line 1014) intersects the second direction A2, and the fourth conditional angle γ2 between the third direction A3 and the second direction A2 is satisfied:

$$tan γ2 = \frac{2 e - ( a - c ) tan α 1}{a - c} \qquad Formula ( 7 )$$

In the above formula (7), e is the distance between two adjacent gate lines 1014 in the first direction A1. Moreover, α1 in the formula (7) may be determined based on the above-described first condition. Thus, by determining the fourth conditional angle γ2 by the above-described formula (7), the influence of the lens structure 1041 and the gate line 1014 can be eliminated simultaneously to produce moiré.

In the embodiments of the present disclosure, a higher number of pixel electrodes b1a can be placed on the first substrate 1011 as much as possible to improve the storage capacitance of the display panel 10. Moreover, the length of the channel of the switching transistor can be improved by designing the transparent electrode layer b4, which in turn avoids the wider design of the gate line 1014, and the opening ratio of the display panel 10 can be improved. The arrangement of pixels in the display panel 10 provided by the embodiments of the present disclosure can ensure low power consumption.

In some embodiments, the materials of the pixel electrode layer b1, the common electrode layer b2, the transparent electrode layer b4, and the electrode transfer layer b14 may all be transparent materials, such as indium tin oxide (ITO).

In summary, the embodiments of the present disclosure provide a display panel. The pixel in an array substrate of the display panel includes a plurality of sub-pixels of different colors, each of the data lines is connected to a column of sub-pixels arranged in a first direction, and each of the gate lines is connected to at least one sub-pixel arranged in the first direction. In addition, the light-emitting region of the sub-pixel is disposed on both sides of the gate line, i.e., span two opening regions disposed on both sides of the gate line, which facilitates realizing the continuous display of two opening regions arranged in the first direction. Moreover, as the black matrix structure does not cover the target line segment of the gate line, the influence of the black matrix structure on the continuous display in the first direction can be avoided, and the continuous display of the display panel in the first direction is ensured, and the display effect of the display panel is better.

FIG. 69 is a schematic structural diagram of a display device according to some embodiments of the present disclosure. Referring to FIG. 69, the display device includes a power supply assembly 20 and a display panel 10 as provided in the above embodiments. The power supply assembly 20 is configured for supplying power to the display panel 10.

In some embodiments, the display device may be a liquid crystal display (LCD) device. The display device may be any suitable display device including, but not limited to, a cell phone, a tablet computer, a television, a monitor, a laptop, a digital photo frame, a navigator, an e-book, and any other product or component with a display function.

As the display device has essentially the same technical effect as the display panel described in the previous embodiments, the technical effect of the display device will not be repeated here for the purpose of brevity.

The terms used in the embodiments of the present disclosure are used only for the purpose of explaining the embodiments of the present disclosure and are not intended to limit the present disclosure. Unless otherwise defined, technical terms or scientific terms used in the embodiments of the present disclosure should have the ordinary meaning understood by a person of ordinary skill in the field to which the present disclosure belongs.

The terms used in the embodiments of the present disclosure are merely intended for the purpose of explaining the embodiments of the present disclosure and are not intended to limit the present disclosure. Unless otherwise defined, technical or scientific terms used in the embodiments of the present disclosure shall have the same meanings as commonly understood by a person of ordinary skill in the art to which the present disclosure belongs. The terms “first,” “second,” “third,” and the like used in the specification and the claims of the present disclosure do not indicate any order, number, or importance, but are used only to distinguish between different components. Likewise, similar words “a” or “an” do not indicate a quantity limitation, but indicate that there is at least one. The terms “include” or “comprise” and the like are intended to indicate that the elements or objects before “include” or “comprise” encompass the elements or objects listed after “include” or “comprise” and their equivalents, and do not exclude other elements or objects. The terms “connect” or “connected” and the like are not limited to physical or mechanical connections, but may include electrical connections, whether direct or indirect. The terms “upper,” “lower,” “left,” “right,” etc. are only used to represent relative position relationships, and when the absolute position of the object to be described changes, the relative position relationship may also be changed accordingly.

The foregoing descriptions are merely optional embodiments of the present disclosure and are not intended to limit the present disclosure. Any modification, equivalent replacement, and improvement within the spirit and principle of the present disclosure shall be included within the protection scope of the present disclosure.

1. A display panel, comprising: an array substrate and a color filter substrate that are arranged oppositely, and a liquid crystal layer disposed between the array substrate and the color filter substrate; wherein the array substrate comprises:
a first substrate;
a plurality of pixels disposed on the first substrate, wherein each of the pixels comprises a plurality of first sub-pixels of a first color, a plurality of second sub-pixels of a second color, and a plurality of third sub-pixels of a third color, wherein a plurality of sub-pixels of each color are arranged in a first direction, and the plurality of first sub-pixels, the plurality of second sub-pixels, and the plurality of third sub-pixels are arranged in a second direction, the second direction and the first direction intersecting;
a plurality of data lines extending in the first direction and arranged in the second direction, wherein each of the data lines is connected to a column of sub-pixels arranged in the first direction; and
a plurality of gate lines extending in a third direction and arranged in the first direction, wherein each of the gate lines is connected to at least one sub-pixel arranged in the first direction, and a light-emitting region of at least a portion of the plurality of sub-pixels comprised in the pixel is disposed on both sides of the gate line, the third direction and the first direction intersecting; and
the color filter substrate comprises a second substrate and a black matrix layer disposed on the second substrate, wherein the black matrix layer comprises a plurality of black matrix structures extending in the first direction and arranged in the second direction, wherein each of the black matrix structures covers at least one of the data lines, and the black matrix layer does not overlap with a target line segment of the gate line, the target line segment being a line segment disposed between adjacent sub-pixels in the first direction and not overlapping with the data line.

2. The display panel according to claim 1, wherein the array substrate further comprises a pixel electrode layer disposed on the first substrate, the pixel electrode layer comprising a plurality of pixel electrodes disposed at intervals;
wherein a shape of an orthographic projection of each of the pixel electrodes on the first substrate is in a strip shape, an extension direction of the pixel electrode intersects the first direction, the second direction, and the third direction, and each of the first sub-pixels, the second sub-pixels, and the third sub-pixels comprises one of the pixel electrodes;
wherein the orthographic projection of the pixel electrode on the first substrate partially overlaps with an orthographic projection of at least one of the gate lines on the first substrate.

3. (canceled)

4. The display panel according to claim 1, wherein in the second direction, a gap is defined between any adjacent sub-pixels of two colors, and at least two of the plurality of data lines are disposed in a same gap, wherein at least one of the data lines disposed in the same gap is connected to one of the adjacent sub-pixels of the two colors, and at least one of the data lines disposed in the same gap is connected to another of the adjacent sub-pixels of the two colors;
each of the gate lines is connected to at least two sub-pixels that are adjacent in the first direction, the third direction and the first direction intersecting; and
each of the black matrix structures covers at least two of the data lines disposed in the same gap.

5. The display panel according to claim 4, wherein two of the plurality of data lines are disposed in the same gap, wherein one of the two data lines is connected to one of the adjacent sub-pixels of the two colors, and another of the two data lines is connected to another of the adjacent sub-pixels of the two colors; or,
three of the plurality of data lines are disposed in the same gap, wherein one of the three data lines is connected to one of the adjacent sub-pixels of the two colors, and another two of the three data lines are connected to another of the adjacent sub-pixels of the two colors; or, two of the data lines disposed in the same gap are connected to one of the adjacent sub-pixels of the two colors, and another of the data lines is connected to another of the adjacent sub-pixels of the two colors.

6. The display panel according to claim 1, further comprising a common electrode layer, wherein the common electrode layer comprises a plurality of first electrode portions arranged in the second direction and a plurality of second electrode portions arranged in the second direction, the plurality of first electrode portions and the plurality of second electrode portions being staggered; wherein
an orthographic projection of each of the first electrode portions on the first substrate is within an orthographic projection of the black matrix structure on the first substrate; and
the second electrode portion comprises a plurality of common electrode patterns arranged at intervals in the first direction, one end of each of the common electrode patterns being connected to one of two adjacent first electrode portions, and another end of each of the common electrode patterns being connected to another of the two adjacent first electrode portions;
wherein a shape of an orthographic projection of each of the common electrode patterns on the first substrate is in a strip shape, an extension direction of the common electrode pattern is parallel to an extension direction of a pixel electrode comprised in the sub-pixel, and an orthographic projection of the common electrode pattern on the first substrate at least partially overlaps with an orthographic projection of the pixel electrodes on the first substrate.

7. The display panel according to claim 1, wherein each of the sub-pixels further comprises a switching transistor comprising a source, a drain, and a channel disposed between the source and the drain, wherein the source is connected to the data line, and the drain is connected to a pixel electrode comprised in the sub-pixel; and
the array substrate comprises a gate layer and a transparent electrode layer in contact with the gate layer, wherein the plurality of gate lines are disposed in the gate layer;
wherein the transparent electrode layer comprises a plurality of transparent electrode patterns, wherein in a fourth direction, an orthographic projection of each of the transparent electrode patterns on the first substrate covers an orthographic projection of each of the gate lines on the first substrate; a length of the orthographic projection of the transparent electrode pattern on the first substrate in the fourth direction is greater than a length of the orthographic projection of the gate line on the first substrate in the fourth direction;
and the length of the orthographic projection of the transparent electrode pattern on the first substrate in the fourth direction is a length of the channel, the fourth direction being perpendicular to the third direction.

8. The display panel according to claim 7, wherein the array substrate comprises a buffer layer, an active layer, a gate insulating layer, the gate layer, the transparent electrode layer, an interlayer dielectric layer, a source-drain layer, a first passivation layer, a first planarization layer, the pixel electrode layer, a second passivation layer, a second planarization layer, and the common electrode layer that are stacked sequentially on the first substrate; wherein
the active layer comprises a plurality of active patterns, wherein each of the active patterns comprises a source region, a drain region, and a channel region;
the interlayer dielectric layer and the gate insulating layer are each provided with a first via, wherein the first via is configured to expose the source region;
the source-drain layer comprises the plurality of data lines and a plurality of source-drain patterns, wherein each of the source-drain patterns is connected to one of the data lines, and each of the source-drain patterns and a source region of one of the active patterns are connected through the first via;
the gate insulating layer, the interlayer dielectric layer, the first passivation layer, and the first planarization layer are each provided with a second via, wherein the second via is configured to expose the drain region;
each pixel electrode in the pixel electrode layer has a first portion disposed within the second via and a second portion disposed on a side of the first planarization layer away from the first substrate, wherein the first portion and the drain region of the active pattern are connected through the second via, and a distance between the first portion and the first substrate is less than a distance between the second portion and the first substrate; and
at least a portion of the second planarization layer is disposed on a side of the first portion away from the first substrate, and a surface of the common electrode layer close to the first substrate is a flat surface.

9. The display panel according to claim 7, wherein the array substrate comprises a buffer layer, an active layer, a gate insulating layer, the gate layer, the transparent electrode layer, an interlayer dielectric layer, a source-drain layer, a first passivation layer, an electrode transfer layer, a first planarization layer, the pixel electrode layer, a second passivation layer and the common electrode layer that are stacked sequentially on the first substrate; wherein
the active layer comprises a plurality of active patterns, wherein each of the active patterns comprises a source region, a drain region, and a channel region;
the interlayer dielectric layer and the gate insulating layer are each provided with a first via, wherein the first via is configured to expose the source region;
the source-drain layer comprises the plurality of data lines and a plurality of source-drain patterns, wherein each of the source-drain patterns is connected to one of the data lines, and each of the source-drain patterns and a source region of one of the active patterns are connected through the first via;
the gate insulating layer, the interlayer dielectric layer, and the first passivation layer are each provided with a third via, wherein the third via is configured to expose the drain region;
the electrode transfer layer comprises a plurality of electrode transfer patterns, wherein each of the electrode transfer patterns and a drain region of one of the active patterns are connected through the third via, and an orthographic projection of the electrode transfer pattern on the first substrate at least partially overlaps with an orthographic projection of the data line on the first substrate;
the first planarization layer is provided with a fourth via, wherein the fourth via is configured to expose the electrode transfer pattern, and an orthographic projection of the fourth via on the first substrate at least partially overlaps with the orthographic projection of the data line on the first substrate; and
each pixel electrode in the pixel electrode layer has a third portion disposed within the fourth via and a fourth portion disposed on a side of the first planarization layer away from the first substrate, wherein the third portion and the electrode transfer pattern are connected through the fourth via, and a distance between the third portion and the first substrate is less than a distance between the fourth portion and the first substrate.

10. The display panel according to claim 9, wherein the first passivation layer comprises a first sub-passivation layer and a second sub-passivation layer; and the array substrate further comprises a shielding layer disposed between the first sub-passivation layer and the second sub-passivation layer, wherein the shielding layer comprises a plurality of shielding patterns, each of the shielding patterns being disposed between the data line and the electrode transfer pattern; and
in the second direction, an orthographic projection of the shielding pattern on the first substrate covers orthographic projections of at least two data lines on the first substrate, and a length of the shielding pattern in the second direction is less than a length of the black matrix structure in the second direction.

11. The display panel according to claim 10, wherein the array substrate further comprises a spacer layer disposed between the first sub-passivation layer and the shielding layer;
wherein an orthographic projection of the spacer layer on the first substrate covers the orthographic projection of the shielding pattern on the first substrate.

12. The display panel according to claim 7, wherein the array substrate comprises a source-drain layer, a buffer layer, an active layer, a gate insulating layer, the transparent electrode layer, the gate layer, a first passivation layer, a first planarization layer, an electrode transfer layer, a second passivation layer, a second planarization layer, the pixel electrode layer, a third passivation layer, and the common electrode layer that are stacked sequentially on the first substrate; wherein
the source-drain layer comprises the plurality of data lines and a plurality of source-drain patterns, wherein each of the source-drain patterns is connected to one of the data lines;
the buffer layer is provided with a fifth via, the fifth via being configured to expose a portion of one of the source-drain patterns;
the active layer comprises a plurality of active patterns, wherein each of the active patterns comprises a source region, a drain region, and a channel region, the source region and the source-drain pattern being connected through the fifth via;
the first passivation layer and the first planarization layer are each provided with a sixth via, wherein the sixth via is configured to expose the drain region;
the electrode transfer layer comprises a plurality of electrode transfer patterns, wherein each of the electrode transfer patterns has a fifth portion disposed within the sixth via and a sixth portion disposed on a side of the first planarization layer away from the first substrate, the fifth portion and the drain region of the active pattern being connected through the sixth via, and a distance between the fifth portion and the first substrate is less than a distance between the sixth portion and the first substrate;
at least a portion of the second planarization layer is within the sixth via, and a surface of the pixel electrode layer close to the first substrate is a flat surface;
the second passivation layer and the second planarization layer are each provided with a seventh via, wherein the seventh via is configured to expose a portion of the sixth portion; and
each pixel electrode in the pixel electrode layer and one sixth portion are connected through the seventh via.

13. The display panel according to claim 7, wherein the array substrate comprises a source-drain layer, a buffer layer, an active layer, a gate insulating layer, the transparent electrode layer, the gate layer, a first passivation layer, an electrode transfer layer, a first planarization layer, the pixel electrode layer, a second passivation layer, and the common electrode layer that are stacked sequentially on the first substrate;
the source-drain layer comprises the plurality of data lines and a plurality of source-drain patterns, wherein each of the source-drain patterns is connected to one of the data lines;
the buffer layer is provided with a fifth via, wherein the fifth via is configured to expose a portion of the source-drain pattern;
the active layer comprises a plurality of active patterns, wherein each of the active patterns comprises a source region, a drain region, and a channel region, the source region and the source-drain pattern being connected through the fifth via;
the first passivation layer is provided with an eighth via, wherein the eighth via is configured to expose the drain region;
the electrode transfer layer comprises a plurality of electrode transfer patterns, wherein each of the electrode transfer patterns and the drain region are connected through the eighth via;
the first planarization layer is provided with a ninth via, wherein the ninth via is configured to expose a portion of the electrode transfer pattern; and
the pixel electrode has a seventh portion disposed within the ninth via and an eighth portion disposed on a side of the first planarization layer away from the first substrate, wherein the seventh portion and the electrode transfer pattern are connected through the ninth via, and a distance between the seventh portion and the first substrate is less than a distance between the eighth portion and the first substrate;
wherein the black matrix structure covers the ninth via.

14. The display panel according to claim 2, wherein the pixel electrode has a first pixel portion, a second pixel portion and a third pixel portion, wherein an orthographic projection of the first pixel portion on the first substrate is within an orthographic projection of a first target black matrix structure on the first substrate, an orthographic projection of the second pixel portion on the first substrate is located between the orthographic projection of the first target black matrix structure on the first substrate and an orthographic projection of a second target black matrix structure on the first substrate, an orthographic projection of the third pixel portion on the first substrate is within the orthographic projection of the second target black matrix structure on the first substrate, the first target black matrix structure and the second target black matrix structure being two black matrix structures that are adjacent in the second direction; and
a length of the first pixel portion in the second direction and a length of the third pixel portion in the second direction are both greater than or equal to 1 μm.

15. The display panel according to claim 1, further comprising a lens layer disposed on a side of the color filter substrate away from the array substrate, wherein the lens layer comprises a plurality of lens structures, a surface of each of the lens structures away from the array substrate being a curved surface;
wherein a shape of an orthographic projection of the lens structure on the array substrate is in a strip shape, and an extension direction of the lens structure intersects the first direction, the second direction and the third direction;
wherein the extension direction of the lens structure intersects an extension direction of the pixel electrode comprised in the sub-pixel.

16. (canceled)

17. The display panel according to claim 15, wherein in a first condition, the first direction is a pixel column direction of the display panel, the second direction is a pixel row direction of the display panel, and a first conditional angle between the extension direction of the pixel electrode and the second direction is satisfied:
$$tan α 1 = \frac{d - b}{a - c} ;$$
an angle between the extension direction of the lens structure and the second direction is satisfied:
$$tan β = \frac{d}{a - c} ;$$
wherein the a is a length of the sub-pixel in the second direction, the b is a length of the sub-pixel in the first direction, the c is a length of the black matrix structure in the second direction, and the d is a length of the lens structure disposed between the two adjacent black matrix structures portions of the lens structure in the first direction; and
the first condition is that a length in the first direction of a portion of the lens structure disposed in an opening region equal to a maximum distance between two ends of the sub-pixel in the first direction.

18. The display panel according to claim 17, wherein, in a second condition, the third direction is parallel to the second direction, and a second conditional angle between the extension direction of the pixel electrode and the second direction is satisfied:
$$tan α 2 = \frac{e}{a - c} ;$$
wherein the e is a distance between two adjacent gate lines in the first direction; and an angle between the extension direction of the pixel electrode and the second direction is a common multiple of the first conditional angle and the second conditional angle; and
the second condition is that a length of a portion of the pixel electrode disposed between adjacent black matrix structures in the first direction is equal to a distance of adjacent gate lines in the first direction.

19. The display panel according to claim 17, wherein in a third condition, the third direction and the second direction intersect, and a third conditional angle between the third direction and the second direction is satisfied:
$$tan γ1 = \frac{e - ( a - c ) tan α 1}{a - c} ;$$
wherein e is a distance between two adjacent gate lines in the first direction; and
the third condition is that a sum of a length in the first direction of a portion of the pixel electrode disposed between adjacent black matrix structures and a length in the first direction of a portion of the gate line disposed between adjacent black matrix structures is equal to a distance of adjacent gate lines in the first direction.

20. The display panel according to claim 17, wherein in a fourth condition, the third direction and the second direction intersect, and a fourth conditional angle between the third direction and the second direction is satisfied:
$$tan γ2 = \frac{2 e - ( a - c ) tan α 1}{a - c} ;$$
wherein e is a distance between two adjacent gate lines in the first direction;
the fourth condition is that a sum of a length in the first direction of a portion of the pixel electrode disposed between adjacent black matrix structures and a length in the first direction of a portion of the gate line disposed between adjacent black matrix structures is equal to a distance between the first target gate line and a second target gate line in the first direction, and a third target gate line is also provided between the first target gate line and the second target gate line, an orthographic projection of the pixel electrode on the first substrate partially overlapping with an orthographic projection of the third target gate line on the first substrate.

21. The display panel according to claim 15, wherein extension directions of the plurality of lens structures in the display panel are parallel, and extension directions of the plurality of pixel electrodes comprised in the pixel electrode layer in the display panel are parallel.

22. A display device, comprising: a power supply assembly and a display panel;
wherein the power supply assembly is configured for supplying power to the display panel; and
the display panel comprises an array substrate and a color filter substrate that are arranged oppositely, and a liquid crystal layer disposed between the array substrate and the color filter substrate; wherein the array substrate comprises:
a first substrate;
a plurality of pixels disposed on the first substrate, wherein each of the pixels comprises a plurality of first sub-pixels of a first color, a plurality of second sub-pixels of a second color, and a plurality of third sub-pixels of a third color, wherein a plurality of sub-pixels of each color are arranged in a first direction, and the plurality of first sub-pixels, the plurality of second sub-pixels, and the plurality of third sub-pixels are arranged in a second direction, the second direction and the first direction intersecting;
a plurality of data lines extending in the first direction and arranged in the second direction, wherein each of the data lines is connected to a column of sub-pixels arranged in the first direction; and
a plurality of gate lines extending in a third direction and arranged in the first direction, wherein each of the gate lines is connected to at least one sub-pixel arranged in the first direction, and a light-emitting region of at least a portion of the plurality of sub-pixels comprised in the pixel is disposed on both sides of the gate line, the third direction and the first direction intersecting; and
the color filter substrate comprises a second substrate and a black matrix layer disposed on the second substrate, wherein the black matrix layer comprises a plurality of black matrix structures extending in the first direction and arranged in the second direction, wherein each of the black matrix structures covers at least one of the data lines, and the black matrix layer does not overlap with a target line segment of the gate line, the target line segment being a line segment disposed between adjacent sub-pixels in the first direction and not overlapping with the data line.
